(19) United States
(12) Patent Application Publication
(10) Pub. No.: US 2026/0362789 A1
(43) Pub. Date: Nov. 12, 2026

(54) Semiconductor Device and Manufacturing Method Thereof

(71) Applicant: Diodes Incorporated, Plano, TX (US)

(72) Inventors: Chih-Hung TSAI, Keelung City (TW); Pin-Hao HUANG, New Taipei City (TW); Bau-Shun HUANG, New Taipei City (TW); Kuo-Liang CHAO, Hsinchu (TW)

(21) Appl. No.: 19/399,996

(22) Filed: Nov. 25, 2025

(30) Foreign Application Priority Data
May 8, 2025 (CN) 202510587149.2

(51) Int. Cl. H10D 84/00; H10D 84/01

(52) U.S. Cl. CPC H10D 84/221; H10D 84/01

(57) ABSTRACT

A semiconductor device includes a first epitaxial layer having opposing first surface and second surface. A second epitaxial layer is disposed on the first surface and has a third surface away from the first epitaxial layer. A first rectifier structure is disposed on the third surface. A first electrode pad is disposed on and electrically connected to the first rectifier structure. A second electrode pad includes a first portion disposed on the third surface, and a second portion extending from the third surface toward the first epitaxial layer, extending through the second epitaxial layer and the first epitaxial layer, and protruding from the second surface of the first epitaxial layer. An electrode structure is disposed on the second surface of the first epitaxial layer, and contacting and surrounding a portion of the second portion of the second electrode pad that protrudes from the second surface of the first epitaxial layer.

### CROSS-REFERENCE TO RELATED APPLICATIONS

This patent application claims priority to China Patent Application No. 202510587149.2, filed on May 8, 2025 and entitled “SEMICONDUCTOR DEVICE AND MANUFACTURING METHOD THEREOF,” which is hereby incorporated by reference herein as if reproduced in its entirety.

### TECHNICAL FIELD

The present disclosure relates generally to the field of semiconductors, and in particular embodiments, to techniques and mechanisms for a semiconductor device and a manufacturing method thereof. In some embodiments, a semiconductor device having double epitaxial layers and a manufacturing method thereof are provided.

### BACKGROUND

The semiconductor integrated circuit industry has experienced rapid growth over the past few decades. Technological advances in semiconductor materials and design have resulted in increasingly compact and complex circuits. The new materials and design advancements have been made possible by technological advances in technologies related to processing and manufacturing.

In the process of semiconductor development, as the minimum size of manufacturable components decreases, the number of interconnected devices per unit area also increases, and the allowable separation distance between conductive elements on current conduction paths is limited, resulting in poor electrical isolation and reduced product reliability. Furthermore, the use of lead-containing solder in semiconductor device packaging is currently the mainstream of semiconductor products. However, with the promulgation and restrictions of EU environmental protection regulations, the search for alternative materials to replace lead solder is ongoing. Currently, lead-free solder remains an unresolved issue and environmental protection requirements fail to be met.

### SUMMARY

Technical advantages are generally achieved, by embodiments of this disclosure which describe a semiconductor device and a manufacturing method thereof.

An embodiment of the present disclosure relates to a semiconductor device, comprising: a first epitaxial layer having a first surface and a second surface opposite to each other; a second epitaxial layer, disposed on the first surface of the first epitaxial layer, and having a third surface away from the first epitaxial layer; a first rectifier structure, disposed on the third surface of the second epitaxial layer; a first electrode structure, disposed on the third surface of the second epitaxial layer, the first electrode structure comprising: a first electrode pad, located on the first rectifier structure and electrically connected to the first rectifier structure; and a second electrode pad, having a first portion located on the third surface of the second epitaxial layer, and a second portion extending from the third surface toward the second surface of the first epitaxial layer, wherein the second portion passes through the first epitaxial layer and the second epitaxial layer, and protrudes from the second surface of the first epitaxial layer; and a second electrode structure, disposed on the second surface of the first epitaxial layer, wherein the second electrode structure contacts a bottom and part of sidewalls of the second portion of the second electrode pad protruding from the second surface.

An embodiment of the present disclosure relates to a method for manufacturing a semiconductor device. The method includes: forming a rectifier structure on a first surface of a substrate, wherein the substrate includes a first epitaxial layer and a second epitaxial layer stacked in a vertical direction, the second epitaxial layer being adjacent to the first surface and the first epitaxial layer being away from the first surface; forming a first dielectric layer covering the substrate and the rectifier structure, wherein the first dielectric layer has a plurality of openings, respectively exposing a portion of the rectifier structure and a portion of the substrate; removing the portion of the substrate exposed by the first dielectric layer to form a first opening, wherein the depth of the first opening is greater than the thickness of the first epitaxial layer and the second epitaxial layer; forming a first electrode structure on the first surface of the substrate and in the first opening; reducing the thickness of the substrate such that the bottom of the first electrode structure protrudes from the substrate; forming a second electrode structure on a second surface of the substrate opposite to the first surface, wherein the second electrode structure covers the bottom of the first electrode structure; and forming a molding material layer surround the second electrode structure and the substrate.

According to one aspect of the present disclosure, a semiconductor device is provided that includes: a first epitaxial layer, having a first surface and a second surface opposite to each other; a second epitaxial layer, disposed on the first surface of the first epitaxial layer and having a third surface away from the first epitaxial layer; a first rectifier structure, disposed on the third surface of the second epitaxial layer; a first electrode structure comprising: a first electrode pad, disposed on the first rectifier structure and electrically connected to the first rectifier structure; and a second electrode pad, comprising: a first portion disposed on the third surface of the second epitaxial layer, and a second portion extending from the third surface of the second epitaxial layer toward the first epitaxial layer, extending through the second epitaxial layer and the first epitaxial layer, and protruding from the second surface of the first epitaxial layer; and a second electrode structure, disposed on the second surface of the first epitaxial layer, and contacting and surrounding a portion of the second portion of the second electrode pad that protrudes from the second surface of the first epitaxial layer.

According to another aspect of the present disclosure, a method is provided that includes: forming a rectifier structure on a first surface of a substrate, the substrate comprising a first epitaxial layer and a second epitaxial layer disposed on the first epitaxial layer, the second epitaxial layer being adjacent to the first surface of the substrate; forming a first dielectric layer on the first surface of the substrate, the first dielectric layer having a plurality of openings exposing a portion of the substrate; forming a first opening extending into the substrate from the first surface of the portion of the substrate exposed by the first dielectric layer, wherein a depth of the first opening is greater than a thickness of the first epitaxial layer and the second epitaxial layer; forming a first electrode structure on the first surface of the substrate and in the first opening; reducing a thickness of the substrate such that the first electrode structure in the first opening protrudes from a second surface of the substrate opposite to the first surface of the substrate; forming a second electrode structure on the second surface of the substrate and covering a portion of the first electrode structure protruding from the second surface of the substrate; and forming a molding material layer surrounding the second electrode structure and the substrate.

According to yet another aspect of the present disclosure, a semiconductor device is provided that includes: a substrate comprising a semiconductor layer, a first epitaxial layer disposed on the semiconductor layer, and a second epitaxial layer disposed on the first epitaxial layer; a first rectifier structure disposed on a top surface of the substrate in a first region of the substrate, and a second rectifier structure disposed on the top surface of the substrate in a second region of the substrate adjacent to the first region; a first electrode disposed in the first region, on the first rectifier structure and electrically connected to the first rectifier structure; a second electrode in the first region, comprising: a first portion disposed on the top surface of the substrate; a second portion extending from the top surface of the substrate, through the substrate, and protruding from the substrate; a third electrode disposed in the second region, on the second rectifier structure and electrically connected to the second rectifier structure, the third electrode electrically connected to the first portion of the second electrode; an electrode structure on a bottom surface of the substrate and covering a portion of the second portion that protrudes from the substrate; and a molding material layer extending from the top surface of the substrate through the substrate, and separating the first region and the second region.

The foregoing has outlined rather broadly the features and technical advantages of the present disclosure in order that the detailed description of the disclosure that follows may be better understood. Additional features and advantages of the disclosure will be described hereinafter which form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

In order to make the above features and advantages of the present disclosure more obvious and easier to understand, various embodiments are described in detail below with reference to the accompanying drawings.

### BRIEF DESCRIPTION OF THE DRAWINGS

Aspects of several embodiments of the present disclosure may be better understood when the following detailed description is read in conjunction with the accompanying drawings. It should be noted that various structures may not be drawn to scale. In fact, the dimensions of the various structures may be arbitrarily enlarged or reduced for clarity of discussion.

FIG. 1 is a cross-sectional view of a semiconductor device according to some embodiments of the present application;

FIG. 2 is a cross-sectional view of a semiconductor device according to some embodiments of the present application;

FIG. 3 is a top view of the semiconductor device according to some embodiments of the present application;

FIG. 4 is a circuit layout diagram of the semiconductor device according to some embodiments of the present application;

FIGS. 5-21 are cross-sectional views of a semiconductor device in one or more stages of a method of manufacturing the semiconductor device according to some embodiments of the present application; and

FIG. 22 is a flowchart of a method of manufacturing a semiconductor device according to embodiments of the present application.

The same or similar components are denoted by the same reference numerals in the drawings and detailed description. Several embodiments of the present disclosure will be immediately understood from the following detailed description taken in conjunction with the accompanying drawings.

### DETAILED DESCRIPTION OF ILLUSTRATIVE EMBODIMENTS

The making and using of embodiments of this disclosure are discussed in detail below. It should be appreciated, however, that the concepts disclosed herein can be embodied in a wide variety of specific contexts, and that the specific embodiments discussed herein are merely illustrative and do not serve to limit the scope of the claims. Further, it should be understood that various changes, substitutions and alterations can be made herein without departing from the spirit and scope of this disclosure as defined by the appended claims.

Furthermore, one or more features from one or more of the following described embodiments may be combined to create alternative embodiments not explicitly described, and features suitable for such combinations are understood to be within the scope of this disclosure. It is therefore intended that the appended claims encompass any such modifications or embodiments.

The following disclosure provides various different embodiments or examples for implementing different features of the presented subject matter. Specific embodiments of components and configurations are described below. Certainly, these are examples only and are not intended to be limiting. In this disclosure, references to forming a first feature over or on a second feature may include embodiments where the first and second features are formed in direct contact, and may also include embodiments where an additional feature is formed between the first feature and the second feature such that the first feature and the second feature may not be in direct contact. In addition, the present disclosure may repeat reference signs and/or letters in various embodiments. Such repetition is for simplicity and clarity and does not in itself indicate relationships between the various embodiments and/or configurations discussed.

Embodiments of the present disclosure are discussed in detail below. It should be appreciated, however, that the present disclosure provides applicable concepts that can be embodied in a wide variety of specific contexts. The specific embodiments discussed herein are illustrative only, and do not limit the scope of the present disclosure.

The embodiments are described in detail with reference to the accompanying drawings, but the embodiments are not intended to limit the scope of the present disclosure. In addition, each figure is only for illustration purposes and may not be drawn based on the original dimension, and therefore the size and ratio may be inconsistent with the actual dimension.

The terms "top," "bottom," and "side" are used with reference to the accompanying drawings and should not be construed as indications of orientation limitations in description of physical devices.

The term "photolithography" refers to a microfabrication process for patterning parts on a thin film or the bulk of a wafer, in which a series of processes are performed in sequence including applying photoresist, exposing, developing, and curing.

The term "front-end processing" refers to processing steps of a semiconductor die, which typically begins with fabrication of circuit elements embedded in and on the die and ends with formation of a passivation layer. The term "front-end etching process" refers to an etching process performed during the front-end processing, which is typically used to form patterns on the surface of the die. A typical “front-end etching process” may include, for example, wet chemical etching.

The term "back-end processing" refers to processing steps of a semiconductor die, which typically begins when the front-end processing is completed and typically includes back grinding, die bonding, wire bonding, molding, sawing, and testing. The term "back-end etching process" refers to an etching process performed during the back-end processing, which may be used to form a pattern on the bottom of the die. A typical "back-end etching process" may include, for example, plasma etching or sawing.

Semiconductor devices of embodiments of the present disclosure do not have lead-containing electrical contact pads, complying with the EU environmental protection regulations. Compared to existing processes, the semiconductor devices of embodiments of the present disclosure further have the following differences and advantages. First, the embodiment semiconductor devices of the present disclosure have multiple epitaxial layers 1 with different concentrations. Unlike existing processes that achieve concentration gradients through diffusion or ion implantation within a single epitaxial layer, the use of the multiple epitaxial layers allows to achieve a larger concentration difference within a smaller thickness range. Further, the embodiment semiconductor devices of the present disclosure use polyimide as a protective layer on the front side of a semiconductor device, eliminating the need of packaging using packaging materials (or molding materials). This not only facilitates heat dissipation but also increases forward transient current. Furthermore, the embodiment semiconductor devices of the present disclosure have a cathode structure protruding out of the bottom surface of the substrate 10, which not only reduces ohmic contact resistance but also further improves heat dissipation capabilities of the semiconductor devices. In view of the above structural features, the embodiment semiconductor devices of the present disclosure can realize a high voltage components (e.g., a voltage higher than 650 volts, or between 650 and 1500 volts) having a thinned substrate 10 (thickness less than or equal to 100 microns).

The semiconductor devices/structures of embodiments of the present disclosure are described in a coordinate system including an X-direction, a Y-direction and a Z-direction perpendicular to each other. The Z-direction represents a vertical direction, i.e., in the top-bottom direction of a semiconductor device. The Z-direction is perpendicular to a plane formed by the X-direction and the Y-direction. The X-direction is in the width direction of the semiconductor device. The Y-direction is in the length direction of the semiconductor device. The plane formed by the X-direction and the Y-direction (X-Y plane) is parallel to (or substantially parallel to) the top surface (or bottom surface) of a substrate of the semiconductor device.

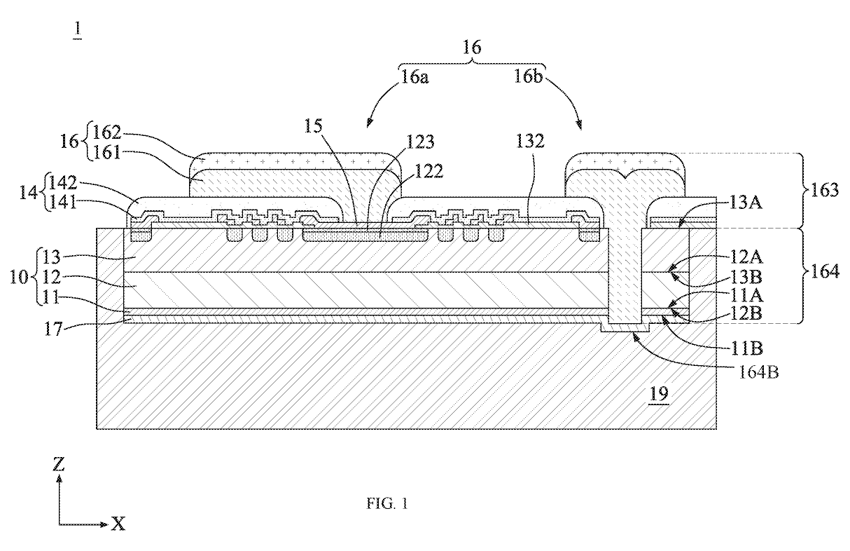

FIG. 1 is a schematic diagram of a semiconductor device 1 according to embodiments of the present disclosure. The figure has been simplified for illustrative purposes to facilitate a better understanding of aspects of the present disclosure. The semiconductor device 1 may be a high-voltage rectifier device (e.g., a high-voltage fast recovery epitaxial diode (FRED)). The semiconductor device 1 may also be referred to as a semiconductor rectifier device 1.

Referring to FIG. 1, the semiconductor device 1 includes a semiconductor layer 11, a first epitaxial layer 12 and a second epitaxial layer 13 disposed on a top surface 11A of the semiconductor layer 11, a rectifier structure 15 disposed on a top surface 13A of the epitaxial layer 13, a first electrode 16a disposed on the rectifier structure 15, and a second electrode 16b extending from above the top surface 13A of the epitaxial layer 13 toward a bottom surface 11B of the semiconductor layer 11.

The semiconductor layer 11 has opposing surfaces 11A and 11B, the first epitaxial layer 12 has opposing surfaces 12A and 12B, and the second epitaxial layer 13 has opposing surfaces 13A and 13B. The semiconductor layer 11, the first epitaxial layer 12, and the second epitaxial layer 13 are stacked in the vertical direction. In some embodiments, the surface 11A of the semiconductor layer 11 contacts the surface 12B of the first epitaxial layer 12, and surface 12A of the first epitaxial layer 12 contacts the surface 13B of the second epitaxial layer 13. For illustration convenience, the stacked structure of the semiconductor layer 11, the first epitaxial layer 12, and the second epitaxial layer 13 is referred to as a substrate 10, where the surface 13A of the second epitaxial layer 13 defines the top surface of the substrate 10, and surface 11B of the semiconductor layer 11 defines the bottom surface of the substrate 10. For illustration convenience, the direction perpendicular to the top surface and the bottom surface of the substrate 10 is defined as the vertical direction, and the direction perpendicular to the vertical direction is defined as the horizontal direction. In some embodiments, the surface 11A, the surface 11B, the surface 12A, the surface 12B, the surface 13A, and the surface 13B are parallel to each other and may be horizontal planes extending in the horizontal direction. The horizontal planes are parallel to the X-Y plane.

The semiconductor layer 11 may be made of polycrystalline silicon or single crystal silicon. The semiconductor layer 11 may include n-type or p-type dopants. For example, the semiconductor layer 11 includes a p-type doped region that may be configured for an n-type transistor and includes an n-type doped region that may be configured for a p-type transistor. The n-type doped region is doped with an n-type dopant, such as phosphorus, arsenic, other n-type dopants, or a combination thereof. The p-type doped region is doped with a p-type dopant, such as boron, indium, other p-type dopants, or a combination thereof. The n-type or p-type doped region may be formed by ion implantation, diffusion, and/or other suitable doping processes. The semiconductor layer 11 has a first-type doped region that extends from the surface 11A toward the surface 11B and covers the entire surface 11A. For illustrative convenience, is described below using the n-type is used as a first-type as an example in the following description, but the present disclosure is not limited thereto. Whether the semiconductor layer 11 is n-type (the first-type) or p-type (a second-type) may be adjusted based on the conductivity type of the semiconductor rectifier device 1. The first-type and the second-type may also be referred to as a first conductivity type and a second conductivity type, respectively.

The first epitaxial layer 12 and the second epitaxial layer 13 are silicon-containing polycrystalline structural layers formed by epitaxial growth. In some embodiments, the first epitaxial layer 12 or the second epitaxial layer 13 includes polycrystalline silicon. The first epitaxial layer 12 and the second epitaxial layer 13 have the same conductivity type as the semiconductor layer 11, that is, the first-type doping. In some embodiments, ions with N-type electrical properties are introduced in the epitaxial growth to form the first epitaxial layer 12 of N-type without the need for additional ion implantation. In some embodiments, the N-type electrical ions are uniformly distributed throughout the first epitaxial layer 12. The semiconductor layer 11 as the drain contact well region of the semiconductor device 1 needs to have a higher first-type doping concentration. In some embodiments, the first-type doping concentration of the first epitaxial layer 12 is less than the first-type doping concentration of the semiconductor layer 11. For formation of the second epitaxial layer 13, reference may be made to the method for forming the first epitaxial layer 12 described above and will not be repeated here. In some embodiments, there may be an observable interface between the first epitaxial layer 12 and the second epitaxial layer 13. In some embodiments, the second epitaxial layer 13 has a resistivity between 15 and 50 ohm-cm. In some embodiments, the first epitaxial layer 12 has a resistivity between 1 and 20 ohm-cm. In some embodiments, the semiconductor layer 11 has a resistivity between 0.01 and 0.06 ohm-cm. A higher doping concentration in the first epitaxial layer 12 helps reduce reverse current recovery time, while a lower doping concentration in the second epitaxial layer 13 helps increase the breakdown voltage (BV). A greater difference in doping concentrations between the first epitaxial layer 12 and the second epitaxial layer 13 (i.e., a greater difference in resistivity, as doping concentration is inversely proportional to resistivity) helps reduce noises. The first and second epitaxial layers 12 and 13 may be formed through different epitaxial growth steps, and they may be designed with significantly different doping concentrations as needed, which thus facilitates to thin the overall thickness of the substrate 10 without causing noise issues. In some embodiments, the thickness of the semiconductor layer 11 ranges from 5 to 30 micrometers (μm). In some embodiments, the thickness of the first epitaxial layer 12 and the thickness of the second epitaxial layer 13 are approximately the same, for example, both are between 10 and 45 micrometers (μm). In some embodiments, the thickness of the first epitaxial layer 12 is less than the thickness of the second epitaxial layer 13. In some embodiments, the thickness of the first epitaxial layer 12 ranges from 5 to 35 micrometers (μm). In some embodiments, the thickness of the second epitaxial layer 13 ranges from 5 to 15 micrometers (μm). In some embodiments, the thickness of the substrate 10 ranges from 30 to 100 micrometers (μm).

The semiconductor device 1 may include a cell region located in a central area and a termination region located in a peripheral area and surrounding the cell region. For the purpose of simplifying the drawings, the cell region and the termination region are not indicated by symbols in the drawings. The second epitaxial layer 13 includes a plurality of doped regions 122 located in the cell region and the termination region, and a plurality of doped regions 123 located in a portion of the doped regions 122. The doped regions 122 extend from the top surface 13A toward the bottom surface 13B of the second epitaxial layer 13 and have a depth that is less than the thickness of the second epitaxial layer 13. That is, the bottom of the doped regions 122 is higher than the surface 13B of the second epitaxial layer 13 in the Z-direction. In some embodiments, adjacent doped regions 122 are separated from each other. In some embodiments, the doped regions 122 have the second conductivity type different from the first conductivity type. The doped regions 123 have the same second conductivity type as the doped regions 122, and their second-type ion doping concentration is higher than the second-type ion doping concentration of the doped regions 122. The doped regions 123 serve as doped contact regions for the electrodes and are therefore disposed in the doped regions 122 that are in contact with or adjacent to the electrodes.

In some embodiments, a first doped region 122 may be located in the cell region, and multiple second doped regions 122 may be located in the termination region. The first doped region 122 may have a width greater than the width of each of the second doped regions 122. The second doped regions 122 may have substantially the same width or different widths. In an example, a first group of the second doped regions 122 may have a same first width, and a second group of the second doped regions 122 may have a same second width different from the first width. As shown in FIG. 1 as an example, the second doped regions 122 located near the two opposing sides of the second epitaxial layer 13 (in the X-direction) have the same width, which is however different from the widths of the second doped regions 122 located farther away from the sides of the second epitaxial layer 13. In some example, the doped region(s) 122 located in the cell region has/have a width different from the doped region(s) 122 located in the termination region. The doped regions 122 are spaced apart along the X-direction. In some embodiments, the doped regions 122 may not be uniformly spaced apart.

In some embodiments, a first doped region 123 may be located in the first doped region 122, and multiple second doped regions 123 may be located in some of the second doped regions 122, e.g., in the second doped regions 122 located near the two opposing sides of the second epitaxial layer 13, as shown in FIG. 1 as an example. The doped region 123 may extend from the surface 13A toward the bottom of the doped regions 122. The doped regions 123 have a depth less than the doped regions 122.

The rectifier structure 15 is disposed on the top surface 13A of the second epitaxial layer 13. In some embodiments, the rectifier structure 15 is located at least in the cell region of the semiconductor device 1 (the figures do not indicate the cell region, but it is understood that the semiconductor device 1 has the cell region located in the central region and the termination region surrounding the cell region). The rectifier structure 15 may be a single-layer structure or a multi-layer structure. In some embodiments, the rectifier structure 15 includes multiple metal layers of different materials. In some embodiments, a portion of the rectifier structure 15 contacts a portion of the top surface 13A of the second epitaxial layer 13. In some embodiments, the material of the rectifier structure 15 includes copper, aluminum, titanium, indium, aluminum, gallium, silicon, an alloy thereof, or a combination thereof.

In some embodiments, the rectifier structure 15 may include a first portion in the cell region and in contact with the top surface 13A of the second epitaxial layer 13, a second portion and a third portion located respectively at opposing edges of the rectifier structure 15 and connected to the first portion. The second portion and the third portion may be referred to as an edge portion of the rectifier structure 15. The edge portion of the rectifier structure 15 may not contact the surface 13A of the second epitaxial layer 13.

In some embodiments, the semiconductor device 1 further includes a dielectric layer 132 disposed on the top surface 13A of the second epitaxial layer 13. In some embodiments, the edge portion of the rectifier structure 15 is separated from the top surface 13A of the second epitaxial layer 13 by the dielectric layer 132.

The semiconductor device 1 may be a single die having a first electrode 16a and a second electrode 16b, which are separated from each other. The first electrode 16a is located on and electrically connected to the rectifier structure 15. In some embodiments, the first electrode 16a contacts the rectifier structure 15. The second electrode 16b extends from above the top surface (i.e., the surface 13A) of the substrate 10 toward the bottom surface (i.e., the surface 11B) of the substrate 10. The second electrode 16b penetrates the substrate 10 and protrudes from the bottom surface 11B of the substrate 10. Specifically, the second electrode 16b has a vertical portion 164 that penetrates the semiconductor layer 11, the first epitaxial layer 12, and the second epitaxial layer 13 to electrically connect to an electrode structure 17 located on the bottom surface 11B of semiconductor layer 11.

The second electrode 16b has another portion 163 extending from the top surface 13A of the substrate 10 away from the substrate 10. The portions 163 and 164 are connected at the top surface 13A of the substrate 10. That is, the portion 163 is outside of the substrate 10, and the vertical portion 164 extends through the substrate 10 and protrudes from the bottom surface 11B of the substrate 10. The bottom surface 164B and a portion of the second electrode 16b near the bottom surface 164B is outside of the substrate 10. The first electrode 16a may also be considered as only including a portion 163 that is over the top surface 13A of the substrate 10. The second electrode 16b does not overlap with the rectifier structure 15 in a top view of the semiconductor device 1.

As used herein, electrodes disposed on the surface 13A are collectedly referred to as an electrode structure 16, and each electrode of the electrode structure 16 is represented by a reference symbol “16x”, where x represents a lowercase letter. For example, the electrode structure 16 includes the first electrode 16a and the second electrode 16b.

In some embodiments, the electrode structure 16 is also referred to as a front electrode structure 16, and the electrode structure 17 is also referred to as a back electrode structure 17. In some embodiments, the electrode structure 17 may be a single metal layer or a multi-layer metal layer structure. For illustrative purposes, the following description and the accompanying drawings take the electrode structure 17 having a single metal layer as an example, but the present disclosure is not limited thereto. In some embodiments, the bottom surface 164B of the second electrode 16b contacts the electrode structure 17. In some embodiments, the electrode structure 17 contacts the bottom surface and bottom sidewalls of the second electrode 16b. The electrode structure 17 may be disposed on the bottom surface 11B of the substrate 10, covering and in contact with the bottom surface 11B and the portion of the second electrode 16b protruding out of the bottom surface 11B. That is, the electrode structure 17 surrounds portion of the second electrode 16b protruding out of the bottom surface 11B. The first electrode 16a and the second electrode 16b function as an anode and a cathode, respectively, during operation of the semiconductor device 1. For illustration convenience, the first electrode 16a is referred to as the anode and the second electrode 16b is referred to as the cathode.

The first electrode 16a and the second electrode 16b may each be a single metal layer conductive structure or a multi-layer conductive structure comprising different metal materials. In some embodiments, the first electrode 16a includes a first conductive material layer 161 and a second conductive material layer 162 located on the first conductive material layer 161. The second conductive material layer 162 may be separated from the top surface 13A of the substrate 10. The first conductive material layer 161 of the first electrode 16a may be in contact with a portion of the rectifier structure 15 (e.g., a portion of the top surface of the rectifier structure 15). In some embodiments, the first conductive material layer 161 includes copper and the second conductive material layer 162 includes tin, but the present disclosure is not limited thereto. The first conductive material layer 161 and the second conductive material layer 162 may include other suitable metal materials, such as tungsten, titanium, platinum, tantalum, etc. In the embodiments of the present disclosure, the semiconductor device 1 does not include lead. In some embodiments, for ease of manufacturing, the second electrode 16b may have a single or multi-layer structure similar to the first electrode 16a. For example, the second electrode 16b may include the first conductive material layer 161 and the second conductive material layer 162 located on the first conductive material layer 161. In other words, the first conductive material layer 161 and the second conductive material layer 162 together define the electrode structure 16, and the electrode structure 16 includes the first electrode 16a as the anode and the second electrode 16b as the cathode of the semiconductor device 1. In some embodiments, the first conductive material layer 161 of the second electrode 16b extends on the top surface 13A of the substrate 10 and extends from the top surface 13A toward the bottom surface 11B of the substrate 10, and penetrate the substrate 10. In some embodiments, the bottom of the second electrode 16b protrudes from the bottom surface of the substrate 10. In some embodiments, the second conductive material layer 162 of the second electrode 16b is located on the first conductive material layer 161 on the top surface 13A of the substrate 10 and is separated from the top surface 13A of the substrate 10.

The second electrode 16b extends from the bottom surface 11B of the 11B of the substrate 10 toward the top surface 13A of the substrate 10, and extends through the substrate 10 and beyond the top surface 13A of the substrate 10. In an example, the first conductive material layer 161 of the second electrode 16b extends from the bottom surface of the 11B of the substrate 10, through the substrate 10, and out of the top surface 13A of the epitaxial layer 12. The second conductive material layer 162 of the second electrode 16b is disposed on a top surface of the first conductive material layer 161 above the top surface 13A of the substrate 10. A top surface of the first electrode 16a may be coplanar with the top surface of the second electrode 16b.

In some embodiments, the electrode structure 16 may be considered as including the first conductive material layer 161 and the second conductive material layer 162 disposed on the first conductive material layer 161. Each electrode of the electrode structure 16 is formed by a portion of the first conductive material layer 161 and a portion of the second conductive material layer 162.

To reduce leakage current, a portion of the first electrode 16a not in contact with the rectifier structure 15 is separated from the top surface 13A of the substrate 10 by a dielectric structure 14, and a portion of the second electrode 16b located above the top surface of the substrate 10 is also separated from the top surface 13A of the substrate 10 by the dielectric structure 14. In an example, the dielectric structure 14 cover only a portion of the rectifier structure 15, and separate this portion the rectifier structure 15 from the electrode 16a. In another example, a first portion of the dielectric structure 14 is between the electrode 16a and the rectifier structure 15, and a second portion of the dielectric structure 14 is between the electrode 16b and the top surface 13A of the substrate 10.

To adapt to the market trend of shrinking product sizes, a dielectric material with good dielectric properties may be selected for the dielectric structure 14. In addition, to achieve good adhesion and reduce the problem of shedding between different dielectrics, the dielectric structure 14 may have multiple layers of materials. For example, the dielectric structure 14 may include a first passivation layer 141 conformally disposed on the substrate 10, the dielectric layer 132, and the rectifier structure 15, and include a second passivation layer 142 covering the first passivation layer 141. The first passivation layer 141 and the second passivation layer 142 may be made of the same material or different dielectric materials (depending on different embodiments, the first passivation layer 141 and the second passivation layer 142 may also be referred to as the dielectric layer 141 and the dielectric layer 142. To distinguish them from the dielectric layer 132, the terms of first passivation layer 141 and second passivation layer 142 are used in description below). In some embodiments, the first passivation layer 141 conformally covers the substrate 10, the dielectric layer 132, and the rectifier structure 15. In some embodiments, the second passivation layer 142 covers the entire first passivation layer 141. In some embodiments, the second passivation layer 142 covers the entire upper surface and sidewalls of the first passivation layer 141. In some embodiments, to ensure good leakage protection in small-sized products, the second passivation layer 142 is made of polyimide, and the first passivation layer 141 is made of silicon nitride, silicon oxide, or a combination thereof to provide better adhesion.

The semiconductor device 1 also includes the electrode structure 17 disposed on the bottom surface 11B of the substrate 10. The electrode structure 17 is electrically connected to the second electrode 16b. In some embodiments, the electrode structure 17 conformally covers the portion of the second electrode 16b that protrudes from the bottom surface 11B of the substrate 10. The semiconductor device 1 may further be coated with a molding material layer 19 disposed on the bottom surface of the substrate 10 and covering the electrode structure 17. The molding material layer 19 protects the electrode structure 17 and fills the scribe lines (dicing streets) to protect the sidewalls of the substrate 10. In some embodiments, the molding material layer 19 has a flat surface facing away from the electrode structure 17. The molding material layer 19 encapsulates the semiconductor device 1 by covering the electrode structure 17 and the sidewalls of the substrate 10.

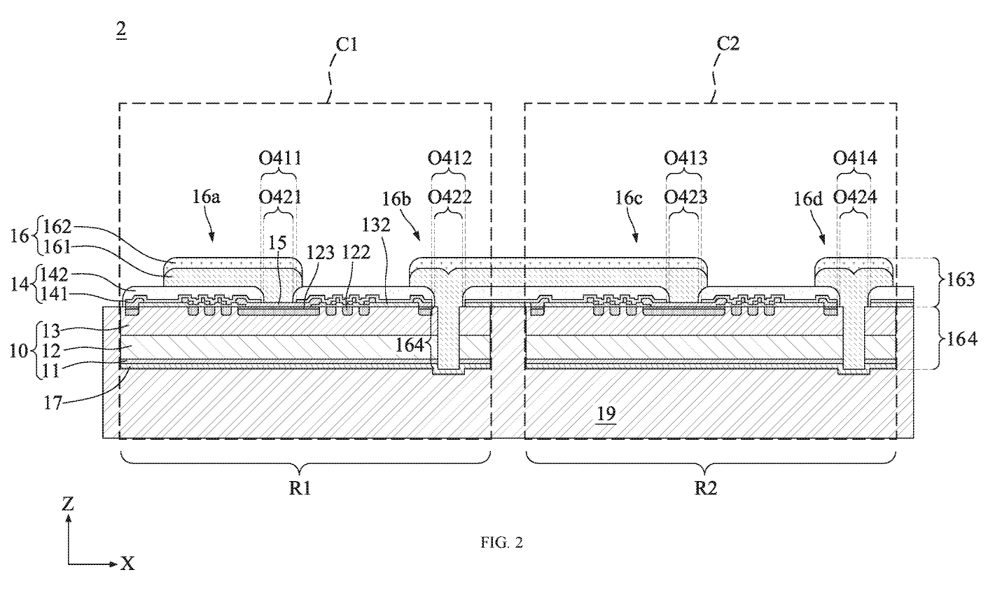

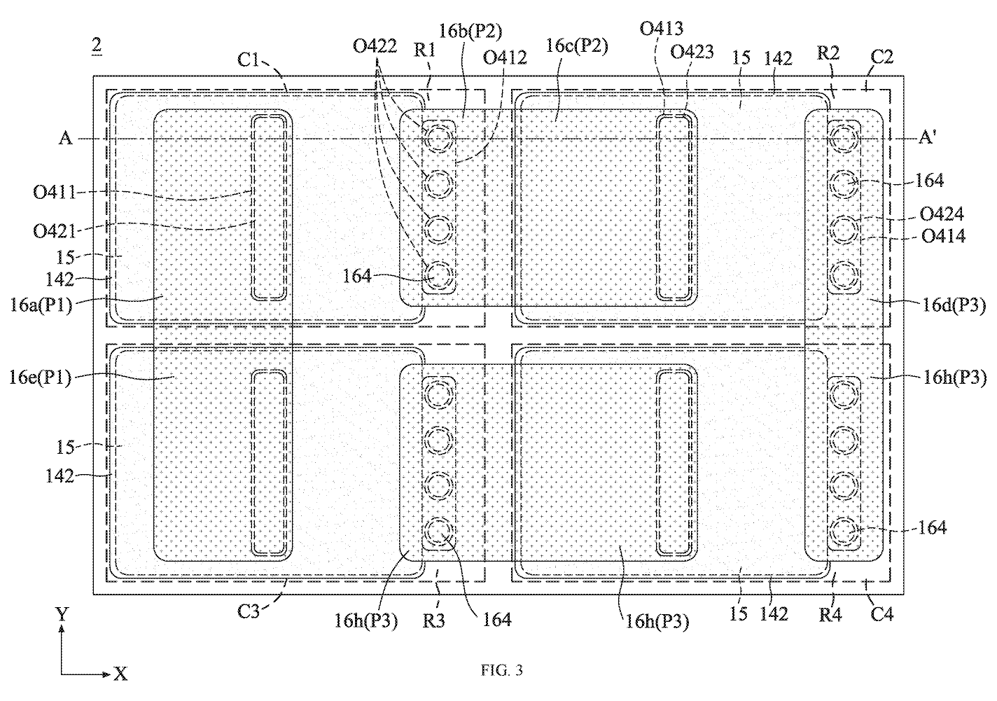

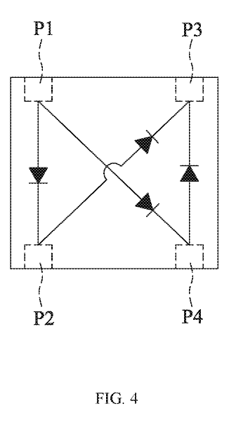

FIGS. 2, 3, and 4 are schematic diagrams of a semiconductor device 2 according to embodiments of the present disclosure. FIG. 2 is a cross-sectional view of the semiconductor device 2 taken along a line AA' in FIG. 3, FIG. 3 is a top view of the semiconductor device 2, and FIG. 4 is a circuit layout diagram of the semiconductor device 2. At least some of these figures have been simplified to facilitate a better understanding of aspects of the present disclosure. The semiconductor device 2 may be a bridge rectifier device. The bridge rectifier device may be use to implement a circuit shown in FIG. 4.

Referring to FIGS. 2 and 3, the semiconductor device 2 includes multiple semiconductor dies, e.g., a first die C1 shown in FIG. 2, a second die C2 adjacent to the first die C1 along a first horizontal direction (e.g., the X-direction), a third die C3 adjacent to the first die C1 along a second horizontal direction (e.g., the Y-direction), and a fourth die C4 adjacent to the third die C3 along the first horizontal direction (the X-direction) and to the second die C2 along the second horizontal direction (the Y-direction). As used herein, the terms “semiconductor die” and “die” are used interchangeably. Each of the semiconductor dies C1, C2, C3, and C4 includes a portion of the substrate 10. In other words, the substrate 10 is divided into multiple regions during a manufacturing process, such as the first and second regions R1 and R2 shown in FIG. 2, and a third region R3 and a fourth region R4 shown in FIG. 3. The multiple regions R1, R2, R3, and R4 correspond to the multiple semiconductor dies C1, C2, C3, and C4, respectively, and the multiple regions R1, R2, R3, and R4 are separated by the molding material layer 19. Each of the semiconductor dies C1, C2, C3, and C4 has a structure similar to that of the semiconductor device 1 described above with respect to FIG. 1. For illustrative purposes, the following description focuses on the portions that are different from the semiconductor device 1, and the portions that are similar or identical to the semiconductor device 1 will not be repeated.

In some embodiments, the substrate 10 may include a plurality of regions that are separated by the molding material layer 19. In some embodiments, the plurality of regions may be arranged in rows and columns (e.g., on the plane defined by the X-direction and the Y-direction), with the molding material layer 19 disposed between the rows and the columns separating the regions. There may be one semiconductor die formed in each of the plurality of regions. The semiconductor dies formed in the plurality of regions may have similar structures. Each of the semiconductor dies may include a portion of the substrate 10. Scribe lines (dicing streets) are provided between the semiconductor dies. In the example embodiments described in the following, the substrate 10 includes the four regions R1-R4, arranged in two rows and two columns on the X-Y plane. The four semiconductor dies C1-C4 are formed in the four regions R1-R4 respectively, and have similar structures. In the following, the first die C1 and the first region R1 are mainly used as an example for illustration purposes. The first die C1 is similar to the semiconductor device 1 in FIG. 1. The descriptions apply similarly to other dies and their corresponding regions.

Referring to FIGS. 2 and 3, each die has a plurality of electrodes. For example, the first die C1 has the first electrode 16a serving as an anode of the first die C1 and the second electrode 16b serving as a cathode of the first die C1, with the anode and cathode being separated from each other. As described above, the plurality of semiconductor die C1, C2, C3, and C4 have similar structures. Similarly, the second die C2 has electrodes 16c and 16d serving respectively as anode and cathode of C2, the third die C3 has electrodes 16e and 16f serving respectively as anode and cathode of C3, and the fourth die C4 has electrodes 16g and 16h serving respectively as anode and cathode of C4.

The substrates 10 of adjacent semiconductor die C1, C2, C3, and C4 are separated by the molding material layer 19. For example, as shown in FIG. 2, a portion of the molding material layer 19 is located between the first region R1 and the second region R2. As another example, as shown in FIG. 3, the molding material layer 19 surrounds each of the semiconductor dies C1, C2, C3, and C4. The molding material layer 19 extends from the top surface 13Aof the substrate 10 to the bottom surface 11B and further covers the electrode structure 17 located on the bottom surface 11B. Specifically, the molding material layer 19 includes a first portion extending from the top surface 13B of the substrate 10 toward the bottom surface 11B and extending through the substrate 10 and the electrode structure 17, where the first portion is between the first die C1 and the second die C2. The molding material layer 19 includes a second portion covering the electrode structure 17 on the bottom surface 11B and covering the first portion of the molding material layer 19.

To achieve the circuit layout shown in FIG. 4 such that the dies C1, C2, C3, and C4 are electrically connected to function as a bridge rectifier, the cathode of the first die C1 and the anode of the second die C2 shown in FIG. 2 need to be electrically connected. As shown in FIG. 2, the second die C2 has the two electrodes 16c and 16d, which serve as the anode and cathode of the second die C2, respectively. For illustrative convenience, the first electrode 16a of the first die C1 is referred to as an anode 16a, and the second electrode 16b is referred to as a cathode 16b. Similarly, the electrode 16c of the second die C2 is referred to as an anode 16c, and the electrode 16d is referred to as a cathode 16d. More generally, in the following, the electrodes 16a, 16c, 16e and 16g may be referred to respectively as anodes 16a, 16c, 16e and 16g, and the electrodes 16b, 16d, 16f and 16h may be referred to respectively as cathodes 16b, 16d, 16f and 16h. In some embodiments, the top surfaces of the electrodes 16a-16h are coplanar. In this example, the electrode structure 16 includes the electrodes 16a-16h, each of which includes a portion of the first conductive material layer 161 and a portion of the second conductive material layer 162.

The cathode 16b of the first die C1 and the anode 16c of the second die C2 are adjacent to each other, they may be electrically connected directly via the first conductive material layer 161 and the second conductive material layer 162. As can be seen from the cross-sectional view in FIG. 2 and the top view in FIG. 3, the cathode 16b of the first die C1 and the anode 16c of the second die C2 each include a portion of the first conductive material layer 161 and a portion of the second conductive material layer 162. The portion of the first conductive material layer 161 located in the first region R1 contacts the portion of the first conductive material layer 161 located in the second region R2, and the portion of the second conductive material layer 162 located in the first region R1 contacts the portion of the second conductive material layer 162 located in the second region R2.

Referring to FIG. 3, the cathode 16b of the first die C1 and the anode 16c of the second die C2 are connected along the first horizontal direction (X-direction), together forming an electrode pad P2. Similarly, the anode 16a of the first die C1 and the anode 16e of the third die C3 are adjacent along the second horizontal direction (Y-direction) and may be directly electrically connected via the first conductive material layer 161 and the second conductive material layer 162, together forming an electrode pad P1. The cathode 16f of the third die C3 and the anode 16g of the fourth die C3 are adjacent along the first horizontal direction and may be directly electrically connected via the first conductive material layer 161 and the second conductive material layer 162, together forming an electrode pad P4. The cathode 16h of the fourth die C4 and the cathode 16d of the second die C2 are adjacent along the second horizontal direction and may be directly electrically connected via the first conductive material layer 161 and the second conductive material layer 162, together forming an electrode pad P3.

The electrode pad P2 includes the cathode 16b of the first die C1, and therefore has the portion 163 of the cathode 16b located over the top surface 12A of the substrate 10, and the portion 164 of the cathode 16b located below the top surface 12A of the substrate 10. Generally speaking, the portion 163 extends horizontally and is therefore also referred to as the horizontal portion 163, and the portion 164 extends vertically and is therefore also referred to as the vertical portion 164. Similarly, the electrode pads P3 and P4 also include the horizontal portions 163 and the vertical portions 164. Since the electrode pad P1 only includes the anode 16a of the first die C1 and the anode 16e of the third die C3, it does not have the vertical portion 164 located below the top surface 12A of the substrate 10 and only has the horizontal portions 163 of the anodes 16a and 16e located above the top surface 12A of the substrate 10.

FIG. 3 shows the top view of the semiconductor device 2 with emphasis on the electrodes. In the top view, the electrodes 16a, 16c, 16e and 16g each extend in the X-direction and the Y-direction, and may each be in a rectangular shape. In the example as shown in FIG. 3, the electrode 16b may include multiple vertical portions 164, each of which is in a cylindrical shape within the substrate 10. The multiple vertical portions 164 may be spaced apart along the Y-direction. The electrodes 16d, 16f and 16h each may also have the similar structure of the multiple vertical portions 164. As shown in FIG. 3, the second conductive material layer 162 is disposed across the regions R1 and R2, R1 and R3, R3 and R4, and R2 and R4. FIGS. 2 and 3 also show positions of openings O411-O414 formed by the first passivation layer 141 and openings O421-O424 formed by the second passivation layer 141, which will be described later.

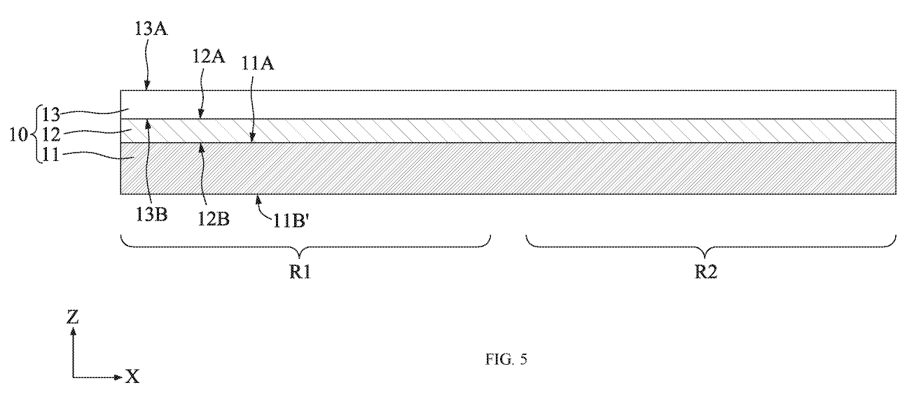

FIGS. 5-19 illustrate one or more stages in a manufacturing method of the semiconductor device 1 according to embodiments of the present application. At least some of these figures have been simplified to facilitate a better understanding of aspects of the present disclosure.

Specifically, FIGS. 5-19 show an embodiment method of manufacturing a semiconductor device including two dies in two regions R1 and R2, where each of the two dies has a similar structure to the semiconductor device 1 as described with respect to FIG. 1. FIGS. 5-19 are cross-sectional views of the semiconductor device in various stages of manufacture. The manufacturing method is described using the formation of the die in the first region R1 as an example for the illustrative convenience. Although only two regions R1 and R2 are shown, the manufacturing method applies similarly to a semiconductor device including more than two regions, such as the semiconductor device 2 as described above with respect to FIG. 2. The steps described below may similarly be applied to each of the regions of the substrate 10 divided for forming corresponding semiconductor dies.

Referring to FIG. 5, the manufacturing method includes sequentially forming the epitaxial layers 12 and 13 on the semiconductor layer 11 to form the substrate 10. In some embodiments, the semiconductor layer 11 comprises the entirety of a silicon wafer or a portion of a silicon wafer near the top surface of the silicon wafer. In some embodiments, the first epitaxial layer 12 is epitaxially grown on the surface 11A of the semiconductor layer 11. In some embodiments, the second epitaxial layer 13 is epitaxially grown on the surface 12A of the first epitaxial layer 12. The semiconductor layer 11, the first epitaxial layer 12, and the second epitaxial layer 13 have the same conductivity type, for example, N-type, and the doping concentration of the semiconductor layer 11 is greater than the doping concentration of the first epitaxial layer 12. In some embodiments, the doping concentration of the first epitaxial layer 12 is less than that of the semiconductor layer 11, and the doping concentration of the second epitaxial layer 13 is less than that of the first epitaxial layer 12. It should be noted that because the semiconductor layer 11 will be thinned in subsequent manufacturing steps, the surface 11B' of the semiconductor layer 11 in the step shown in FIG. 5 is different from the surface 11B shown in FIGS. 1 or 2. The surfaces of 13A and 13B may be considered as the top surface and the bottom surface of the second epitaxial layer 13, respectively. The surfaces of 12A and 12B may be considered as the top surface and the bottom surface of the first epitaxial layer 12, respectively. The surfaces of 11A and 11B' may be considered as the top surface and the bottom surface of the semiconductor layer 11, respectively. The surface 13A is the top surface of the substrate 10.

In some embodiments, the semiconductor layer 11 may be implanted with ions such that at least a portion of the wafer near the surface 11A has N-type conductivity. In some embodiments, ions with N-type conductivity may be introduced during the epitaxial growth process to form the first epitaxial layer 12 of N-type without the need for additional ion implantation. Similarly, in some embodiments, ions with N-type conductivity may be introduced during the epitaxial growth process to form the second epitaxial layer 13 of N-type without the need for additional ion implantation. In some embodiments, ions with N-type conductivity may be uniformly introduced during the epitaxial growth process to form the first epitaxial layer 12 or the second epitaxial layer 13 having a uniform doping concentration, where the ion concentration introduced during the epitaxial growth process does not change over time.

In some embodiments, the second epitaxial layer 13 may have a doping concentration gradient that increases from the surface 13A to the surface 13B. In some embodiments, the increasing doping concentration gradient may be adjusted according to the withstand voltage and resistance required by the product. In some embodiments, ions with N-type electrical properties are introduced during the epitaxial growth process, where the concentration of the introduced ions decreases with the time of epitaxial growth, so as to form the second epitaxial layer 13 having a doping concentration that increases from the surface 13A to the surface 13B. Similarly, the first epitaxial layer 12 may also have a doping concentration that increases from the surface 12A to the bottom surface 12B as needed. In addition, the semiconductor layer 11 may be provided, by ion implantation, with a concentration gradient that increases from the surface 11A to the surface 11B'. Regardless of whether the semiconductor layer 11, the first epitaxial layer 12, or the second epitaxial layer 13 has a uniform or non-uniform doping concentration, in order to achieve the aforementioned effect of the concentration difference, the doping concentration of the semiconductor layer 11 may still be greater than the doping concentration of the first epitaxial layer 12, and the doping concentration of the first epitaxial layer 12 may still be greater than the doping concentration of the second epitaxial layer 13. In some embodiments, the substrate 10 has a doping concentration that increases gradually from the top surface (e.g., the surface 13A of the second epitaxial layer 13) to the bottom surface (e.g., the surface 11B' of the semiconductor layer 11).

Furthermore, the substrate 10 may be divided into multiple regions, such as the first region R1 and the second region R2, each representing the location of different dies to be formed later. For example, the first region R1 and the second region R2 may each be formed into a single die similar to the semiconductor device 1 shown in FIG. 1, or the first region R1 and the second region R2 may each be formed into the first die C1 and the second die C2 as shown in FIG. 2.

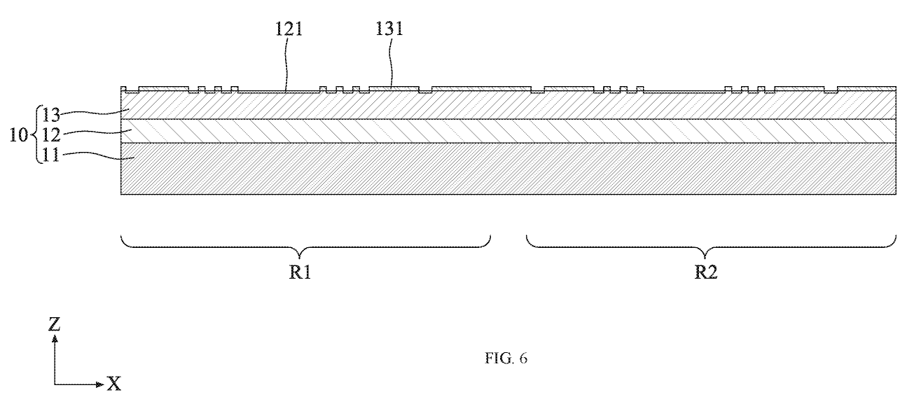

Referring to FIG. 6, the manufacturing method includes forming a patterned mask layer 131 on the surface 13A of the second epitaxial layer 13 and performing ion implantation on the second epitaxial layer 13 using the patterned mask layer 131 as a mask, to form a plurality of doped regions 121 in the second epitaxial layer 13 adjacent to the surface 13A. In some embodiments, the doped regions 121 may extend from the surface 13A toward the surface 13B.

The patterned mask layer 131 may be a dielectric layer, and its material may be, for example, a nitride, oxide, oxynitride, or a combination thereof. In some embodiments, a dielectric layer may be formed on the surface 13A of the second epitaxial layer 13, and a patterned photoresist layer may then be formed on the dielectric layer. The dielectric layer is then etched using the patterned photoresist layer as a mask to form the patterned mask layer 131. The patterned mask layer 131 has a plurality of openings located in the first region R1 and a plurality of openings located in the second region R2. The openings in the patterned mask layer 131 define the locations of the doped regions 121 to be formed in subsequent steps. The openings in the patterned mask layer 131 expose portions of the top surface 13A of the substrate 10/the second epitaxial layer 13 (consequently, exposing a portion of the substrate 10), through which the doped regions 121 are formed. The patterned mask layer 131 may be a dielectric layer, and may also be referred to as a dielectric layer 131 in the following.

Ion implantation may then be performed on the substrate 10 using the patterned mask layer 131 as a mask to form the plurality of doped regions 121 in the second epitaxial layer 13 adjacent to the top surface of the substrate 10. In some embodiments, the patterned photoresist layer is removed prior to the ion implantation step. The doped regions 121 have a conductivity type different than the second epitaxial layer 13, such as P-type. In some embodiments, the P-type ion doping concentration in the doped regions 121 is greater than the N-type ion doping concentration in the second epitaxial layer 13.

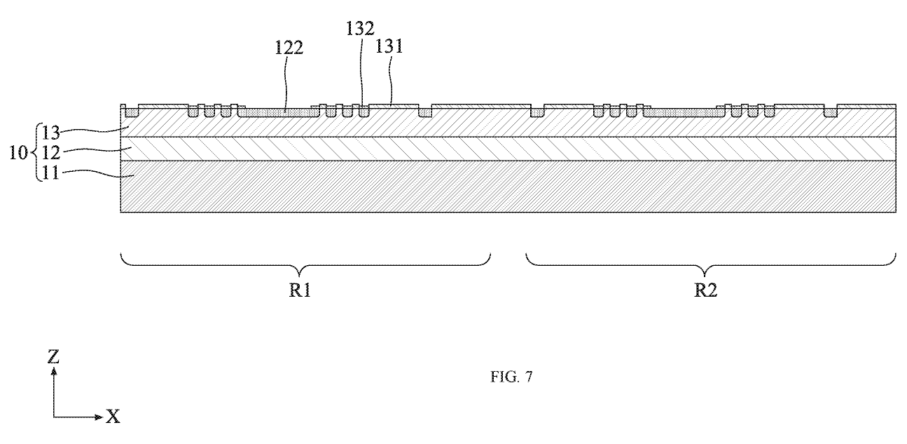

Referring to FIG. 7, the manufacturing method includes: performing a thermal annealing process on the substrate 10 to diffuse the doping ions in the doped regions 121 to form the doped regions 122, and forming the dielectric layer 132 on the exposed substrate 10. The doped regions 122 are formed of the doped regions 121 being diffused. Therefore, the doped regions 122 have the same conductivity type as the doped regions 121 but a lower doping concentration, and the depth of the doped regions 122 is greater than the depth of the doped regions 121. In some embodiments, the dielectric layer 132 is formed after the doped regions 122 are formed. In some embodiments, the surface 13A of the second epitaxial layer 13 is oxidized to form the dielectric layer 132 on the exposed surface 13A of the second epitaxial layer 13. In some embodiments, the sidewalls of the dielectric layer 132 contact the sidewalls of the dielectric layer 131, and the dielectric layer 132 does not cover the top surface of the dielectric layer 131. In some embodiments, the dielectric layer 132 may be deposited to cover the exposed surface 13A of the second epitaxial layer 13 and the dielectric layer 131. In some embodiments, the thickness of the dielectric layer 132 is less than the thickness of the dielectric layer 131, but the disclosure is not limited thereto. In other embodiments, the thickness of the dielectric layer 132 is greater than or equal to the thickness of the dielectric layer 131.

In other words, the top surfaces of the doped regions 122 are coplanar with the top surface 13A of the substrate 10. The dielectric layer 132 is disposed on and covering the top surfaces of the doped regions 122. The dielectric layer 132 may not overlap with the dielectric layer 132 in a top view of the semiconductor structure of FIG. 7, and the dielectric layer 132 may adjoin the dielectric layer 131 along the X-direction.

In some embodiments, the manufacturing method further includes removing a portion of the dielectric layer 132 to expose a portion of the second epitaxial layer 13 that is to contact a later-formed anode. To reduce resistance, the portion of the second epitaxial layer 13 that is to contact the anode requires a higher doping concentration of second-type ions. Therefore, the portion of the dielectric layer 132 is removed to expose a portion of the doped regions 122 within the second epitaxial layer 13 (i.e., exposing a portion of the second epitaxial layer 13).

Specifically, after the portion of the dielectric layer 132 is removed, the top surfaces of some of the doped regions 122 are entirely exposed, e.g., the doped regions 122 located at peripheral of each of the regions R1 and R2 (referred to as a first group of the doped regions 122); and the top surfaces of some of the doped regions 122 are partially exposed, e.g., the doped regions 122 located in the respective cell regions of the regions R1 and R2 (referred to as a second group of the doped regions 122). The exposed top surfaces of the doped regions 122 corresponds to a portion of the doped regions 122 that is exposed through removal of the portion of the dielectric layer 132, which may be considered as a portion of the second epitaxial layer 13 being exposed. As a result, the dielectric layer 132 is disposed on and covers the top surfaces of some other doped regions 122 (referred to as a third group of the doped regions 122), and a portion of the top surface of the second group of the doped regions 122, as shown in FIG. 7.

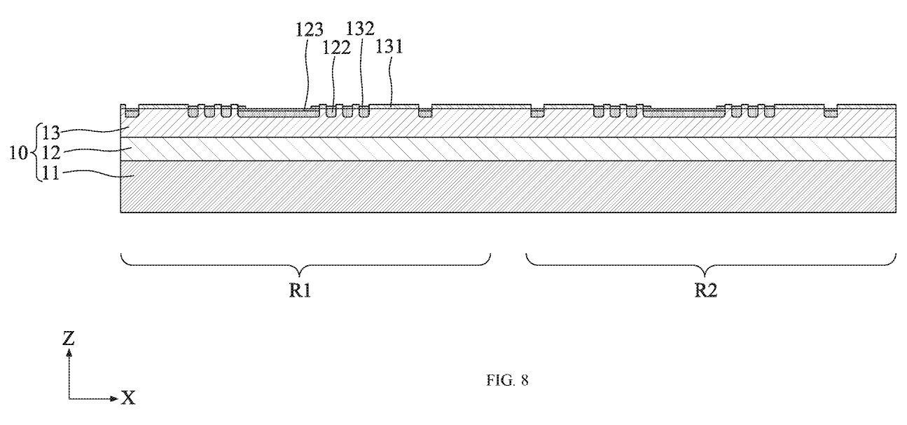

Referring to FIG. 8, the manufacturing method includes performing ion implantation on the exposed second epitaxial layer 13 to form the doped regions 123. The doped regions 123 are formed in the portion of the doped regions 122 adjacent to the surface 13A of the second epitaxial layer 13. The doped regions 123 have the same conductivity type as the doped regions 122, have a higher doping concentration than the doped regions 122, and have a depth less than that of the doped regions 121. In some embodiments, the doped regions 123, serving as the anode contact doped region, is formed in the doped regions 122 located in the center of each region R1 or R2. In some embodiments, the doped region 123 may further be formed in the doped regions 122 located in the peripheral region of each region of R1 and R2.

Specifically, the doped regions 123 are formed in the first group and the second group of the doped regions 122, extending from the top surface 13A of the epitaxial layer 13 toward the bottom surfaces of the corresponding doped regions 122. The top surfaces of the doped regions 123 are coplanar with the top surface 13A.

In some embodiments, prior to the ion implantation to form the doped region 123, a platinum (Pt) layer may be sputtered on the surface 13A of the second epitaxial layer 13, followed by a thermal annealing step to diffuse the Pt ions into the doped regions 122. The doped regions 122 and/or 123 containing Pt ions help reduce power consumption of the semiconductor device 1 or 2.

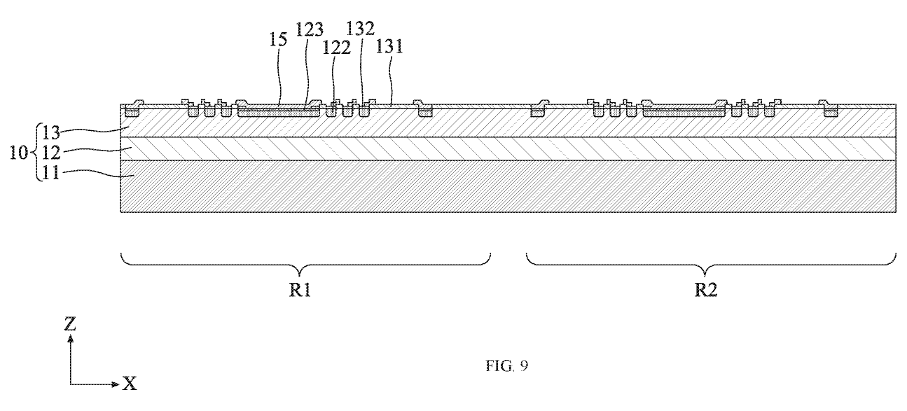

Referring to FIG. 9, the manufacturing method includes forming the rectifier structure 15, where the rectifier structure 15 covers at least the doped regions 123. In some embodiments, the rectifier structure 15 contacts the portion of the substrate 10 exposed by the dielectric layers 131 and 132 and abuts the doped regions 123 in the second epitaxial layer 13. In some embodiments, the rectifier structure 15 further covers a portion of the dielectric layer 131 and/or the dielectric layer 132.

Specifically, the rectifier structure 15 includes a portion formed on and in contact with the doped regions 123, a portion formed on and in contact with a portion of the dielectric layer 131, and a portion formed on and in contact with a portion of the dielectric layer 132.

The rectifier structure 15 may include a single metal layer or multiple metal layers. In some embodiments, the rectifier structure 15 includes a single metal layer, as shown in the accompanying drawings. In other embodiments, the rectifier structure 15 includes at least two metal layers stacked in the vertical direction. For example, the rectifier structure 15 may include a first metal layer and a second metal layer covering the first metal layer. The first metal layer may be, for example, a Schottky metal layer, which contacts the surface 13A of the second epitaxial layer 13 to form a Schottky junction. The second metal layer may serve as a conductive structure, for example, to provide an electrical connection between other conductive pads or conductive lines and the first metal layer.

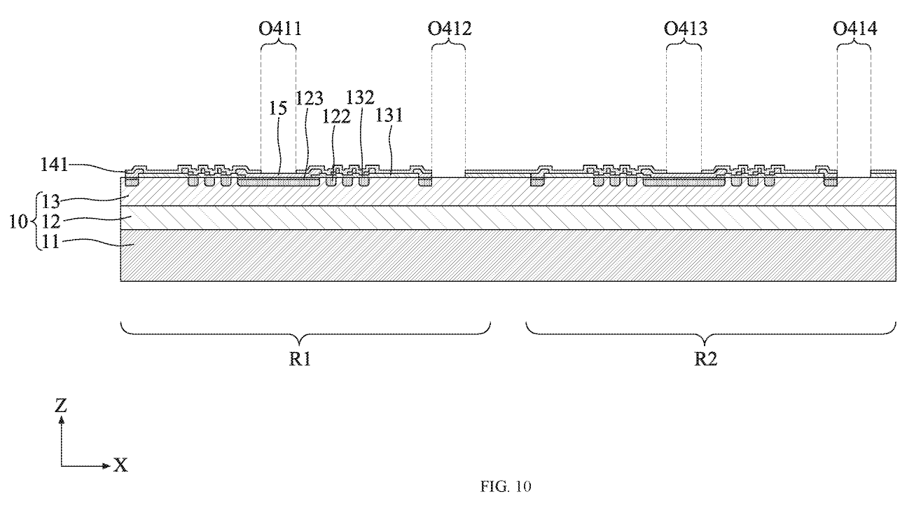

Referring to FIG. 10, the manufacturing method includes forming the first passivation layer 141 covering the rectifier structure 15 and the dielectric layers 131 and 132. In some embodiments, the material of the first passivation layer 141 includes nitride, oxide, oxynitride, or a combination thereof. The first passivation layer 141 may serve as an adhesion layer between the subsequently formed second passivation layer 142 and the underlying material. The first passivation layer 141 may be formed by chemical vapor deposition (CVD), physical vapor deposition (PV ), or a combination thereof.

The first passivation layer 141 has multiple openings in each region (e.g., R1, R2) of the substrate 10, defining locations of the anode and cathode contacts to be formed later. For example, the first passivation layer 141 has an opening O411 and an opening O412 in the first region R1. The opening O411 exposes at least a portion of the rectifier structure 15 on a doped region 123 located in the central region of the first region R1, and the opening O412 exposes a portion of the substrate 10 located in the peripheral region of the first region R1. The opening O411 exposes partially the top surface of the rectifier structure 15 in the first region R1. The vertical projection of the opening O412 does not overlap with the vertical projection of the doped regions 123 and/or the doped regions 122 (may be adjacent to or separated from).

For another example, the first passivation layer 141 has an opening O413 and an opening O414 in the second region R2. The opening O413 exposes at least a portion of the rectifier structure 15 on the doped region 123 located in the central region of the second region R2, and the opening O414 exposes a portion of the substrate 10 located in the peripheral region of the second region R2. The opening O413 exposes partially the top surface of the rectifier structure 15 in the second region R2. The vertical projection of the opening O414 does not overlap with the vertical projection of the doped regions 123 and/or the doped regions 122 (and may be adjacent to or separated from).

The dielectric layer 131 and the dielectric layer 132 may be made of the same dielectric material, and the boundary lines between the adjacent portions of the dielectric layer 131 and the dielectric layer 132 are thus omitted for illustrative simplicity in the subsequent figures.

In some embodiments, the method further includes removing a portion of the dielectric layer 131 and/or the dielectric layer 132 exposed by the first passivation layer 141 to expose a portion of the substrate 10. For example, a portion of the dielectric layer 131 in the first region R1 corresponding to the location of the opening O412 is removed to expose a portion of the substrate 10 (or a portion of the second epitaxial layer 13) corresponding to the opening O412. Thus, the opening O412 exposes the portion of the substrate 10. Another portion of the substrate 10 is exposed by the opening O414 in the second region R2 similarly.

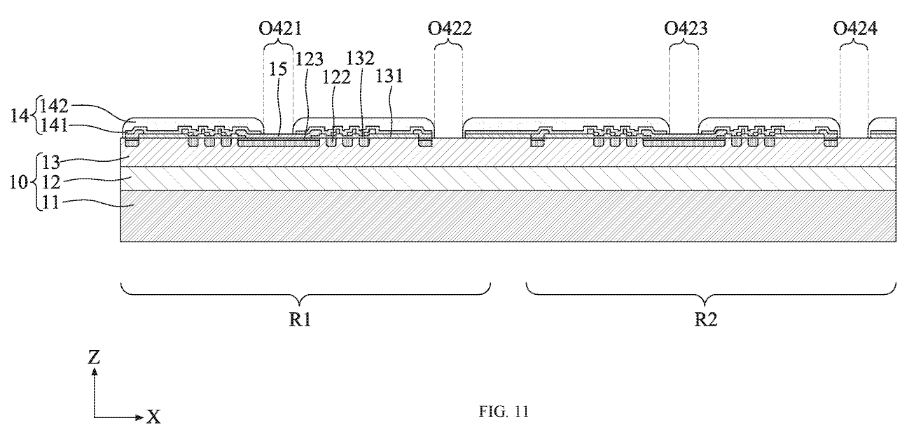

Referring to FIG. 11, the manufacturing method includes forming the second passivation layer 142 covering the first passivation layer 141. The first passivation layer 141 and the second passivation layer 142 constitute the dielectric structure 14. The second passivation layer 142 is configured to electrically isolate the anode and cathode to be formed later from the rectifier structure 15 and the substrate 10, respectively, and also has multiple openings defining the positions of the anode contacts and cathode contacts to be formed later. In some embodiments, the second passivation layer 142 covers the edges of the first passivation layer 141. In some embodiments, the second passivation layer 142 covers the entire top surface and sidewalls of the first passivation layer 141. In some embodiments, the second passivation layer 142 has multiple openings corresponding to the multiple openings in the first passivation layer 141. For example, the second passivation layer 142 has an opening O421 and an opening O422 in the first region R1, where the opening O421 corresponds to the opening O411 and the opening O422 corresponds to the opening O412. The width of the opening O421 is smaller than the width of the opening O411, and the opening O421 exposes a portion of the rectifier structure 15 located in the opening O411. In other words, the opening O421 exposes a portion of the rectifier structure 15 that is exposed by the opening O411. The width of the opening O422 is smaller than the width of the opening O412, and the opening O422 exposes a portion of the substrate 10 located in the opening O412. In other words, the opening O422 exposes a portion of the substrate 10 that is exposed by the opening O412.

For another example, the second passivation layer 142 has an opening O423 and an opening O424 in the second region R2. The opening O423 corresponds to the opening O413, and the opening O424 corresponds to the opening O414. The width of the opening O423 is smaller than that of the opening O413, and the opening O423 exposes a portion of the rectifier structure 15 located in the opening O413. In other words, the opening O423 exposes a portion of the rectifier structure 15 that is exposed by the opening O413. The width of opening O424 is smaller than that of the opening O414, and the opening O424 exposes a portion of the substrate 10 located in the opening O414. In other words, the opening O424 exposes a portion of the substrate 10 that is exposed by the opening O414. In some embodiments, the second passivation layer 142 further covers the sidewalls of the dielectric layer 131 and/or the dielectric layer 132 adjacent to the opening O412. In some embodiments, the second passivation layer 142 further covers the sidewalls of the dielectric layer 131 and/or the dielectric layer 132 adjacent to the opening O414.

In some embodiments, after forming the first passivation layer 141 and before forming the second discontinuing layer 142, a sinter process may be performed and the intermediate structure of FIG. 10 may be tested. The first passivation layer 141 and components formed therebefore may be manufactured in a semiconductor front-end process facility, and the second passivation layer 142 and components formed therefrom may be manufactured in a packaging facility. Therefore, before forming the second passivation layer 142, that is, before the intermediate structure of FIG. 10 is sent to the packaging facility, circuit testing may be performed. In some embodiments, the first passivation layer 141 and the second passivation layer 142 may be manufactured in different facilities and therefore patterned using different photomasks, but the present disclosure is not limited thereto. Depending on the process capabilities of the manufacturing facilities, the above steps may be adjusted accordingly. In other embodiments, the first passivation layer 141 and the second passivation layer 142 may be patterned using the same photomask. In some embodiments, the material of the second passivation layer 142 includes polyimide, and after a photolithography process (e.g., including exposure, development, and curing), a configuration with rounded-corners as shown in FIG. 11 is formed. That is, portions of the second passivation layer 142 separated by the openings O421-O424 have rounded upper corners.

The top view shown in FIG. 3 may be referenced for the positions and configurations of the openings O411, O412, O413, O414 and the openings O421, O422, O423, and O424. The configurations of the openings O411, O412, O413, O414, and the openings O421, O422, O423, and O424 may or may not respectively correspond to each other. Referring back to FIG. 3, as an example, the opening O411 and the opening O421 may have corresponding shapes, while the opening O422 is located within the opening O412 and does not have a shape corresponding to the opening O412. In some embodiments, as shown in FIG. 3, the second passivation layer 142 may have a plurality of openings O422, in the opening O412, corresponding to the number of the vertical portions 164 of the cathode in the first region R1. In some embodiments, the plurality of openings O422 may be separated from each other, all of which are located within the opening O412, and the width of a single opening O422 is smaller than the width of the opening O412. The plurality of openings O422 may have the same width or different widths. The plurality of openings O422 may be evenly arranged along the Y-direction within the opening O412. The plurality of openings O422 define the positions and configurations of the vertical portions 164. Similarly, the second passivation layer 142 may have a plurality of openings O424, in the opening O414, corresponding to the number of the vertical portions 164 of the cathode in the second region R2. As shown in the top view of FIG. 3 as an example, the openings O411, O421, O412, O413, O423, and O414 have shapes of rectangles, and the openings O422 and the openings O424 have shapes of circles.

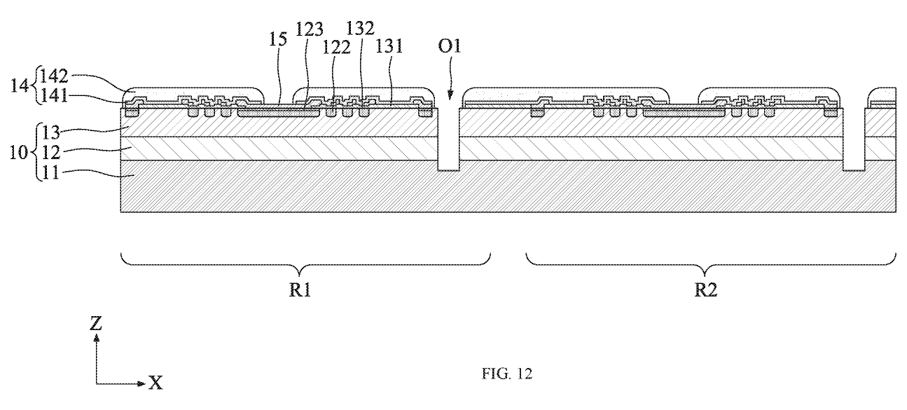

Referring to FIG. 12, the manufacturing method includes etching the substrate 10 to form openings O1. In some embodiments, a patterned photoresist layer may be formed on the intermediate structure shown in FIG. 11 to expose the substrate 10 in the openings O422 and O424. The exposed substrate 10 is then etched to form the openings O1. In some embodiments, a protective layer (e.g., a dielectric layer) may be formed on the structure shown in FIG. 9 to expose the substrate 10 in the openings O422 and O424. The exposed substrate 10 is then etched to form the openings O1. In some embodiments, the etching process on the substrate 10 is performed for a predetermined length of time to control the openings O1 to stop in the semiconductor layer 11. The openings O1 do not penetrate the substrate 10. In some embodiments, the width of an opening O1 is less than the minimum width of the openings O422 or O424. In some embodiments, the shape of the openings O1 corresponds to the shape of the openings O422 or O424, and the configuration of the openings O1 defines the configuration of the vertical portions 164 of the cathode to be formed later (the configuration of the openings O1 can be seen in FIGS. 1, 2, and 3, as shown by the configuration of the vertical portions 164). In some embodiments, the patterned photoresist layer or protective layer is removed after the etching process.

Specifically, the substrate 10 exposed by the opening(s) O422 and the opening(s) 0424 is etched to form the openings O1. The opening(s) O1 in the first region R1 corresponds to the opening(s) O422, and the opening(s) O1 in the second region R2 corresponds to the opening(s) O424. The openings O1 extend from the top surface 13A of the substate 10 toward the bottom surface 11B of the substrate 10 and into the semiconductor layer 11. The bottom surfaces of the openings O1 are between the bottom surface 12B of the first epitaxial layer 12 and the bottom surface 11B of the substrate 10. That is, the openings O1 expose portions of the semiconductor layer 11.

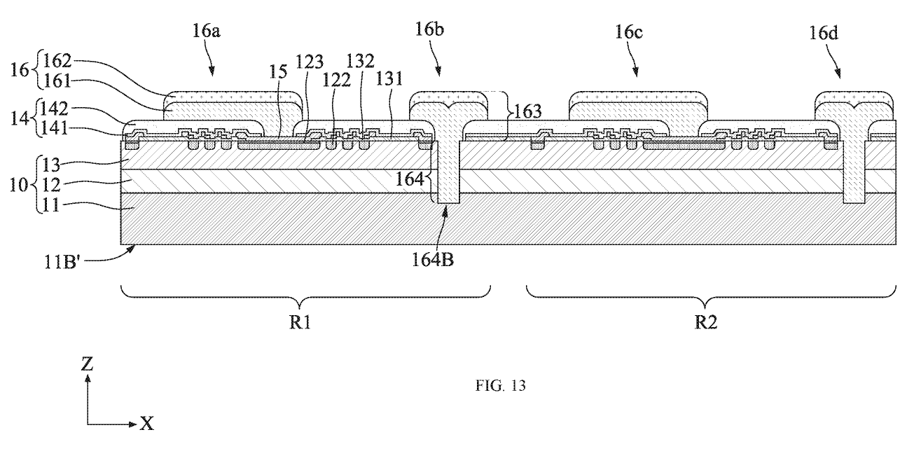

Referring to FIG. 13, the manufacturing method includes forming the first conductive material layer 161 to fill multiple openings (e.g., the openings O421, O422, O423, and O424) in the second passivation layer 142 and the openings O1 in the substrate 10, and forming the second conductive material layer 162 to cover the first conductive material layer 161. The method of forming the first conductive material layer 161 and the second conductive material layer 162 may include: forming a seed layer on the top surface of the intermediate structure shown in FIG. 12; then forming a patterned photoresist layer (or a patterned dielectric layer) on a portion of the seed layer to cover regions other than the cathode and anode; and then performing an electroplating process on the entire substrate 10. The patterned photoresist layer exposes partially the seed layer. Because the regions other than the cathode and anode are covered with the patterned photoresist layer (or the patterned dielectric layer), the first conductive material layer 161 and the second conductive material layer 162 are not formed in the regions other than the cathode and anode during electroplating. The electroplating process may include sequentially electroplating a first conductive material and electroplating a second conductive material to form the first conductive material layer 161 including the first conductive material and the second conductive material layer 162 including the second conductive material.

In some embodiments, the first conductive material layer 161 may include copper, and the second conductive material layer 162 may include tin. In embodiments of the present disclosure, the semiconductor device 2 does not contain lead. In some embodiments, after the electroplating process, the patterned photoresist layer (or the patterned dielectric layer) is removed. In some embodiments, after removing the patterned photoresist layer (or the patterned dielectric layer), the exposed seed layer is removed (e.g., using wet etching). In some embodiments, the second conductive material layer 162 is subjected to a reflow process to form a configuration with rounded corners as shown in the accompanying drawings. The first conductive material layer 161 is filled in the openings O1, and a portion of the first conductive material layer 161 filled in the openings O1 serves as the vertical portion 164 of the cathode, for electrically connecting to the electrode structure 17 to be formed later. The portion 164 has a bottom surface 164B in the semiconductor layer 11. A portion of the first conductive material layer 161 and the second conductive material layer 162 located on the top surface of the substrate 10 (that is, the surface 13A of the second epitaxial layer 13) serves as the horizontal portions 163 of the anode and cathode, for providing an electrical path (or electrical contact point) connected to an external voltage.

As described above with respect to FIG. 1, the first conductive material layer 161 and the second conductive material layer 162 jointly define the electrode structure 16, where a portion of the electrode structure 16 located in the first region R1 and electrically connected to the rectifier structure 15 serves as the anode 16a; a portion of the electrode structure 16, which is located in the first region R1, has a vertical portion 164 and is separated from the anode 16a, serves as the cathode 16b; a portion of the electrode structure 16 located in the second region R2 and electrically connected to the rectifier structure 15 serves as the anode 16c; and a portion of the electrode structure 16, which is located in the second region R2, has a vertical portion 164 and is separated from the anode 16c, serves as the cathode 16d.

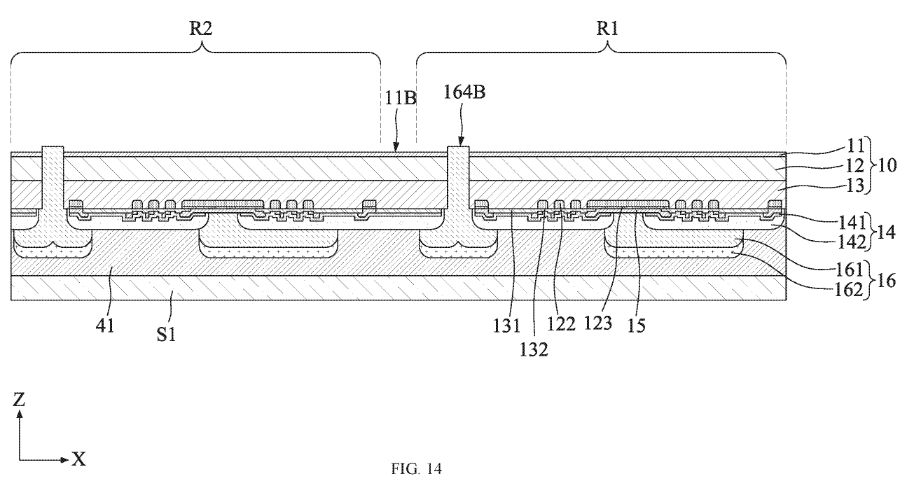

Referring to FIG. 14, the manufacturing method includes thinning the substrate 10 so that the bottom 164B of the vertical portion 164 in the substrate 10 is exposed and protrudes from the substrate 10. In some embodiments, to remove a portion of the semiconductor layer 11 from the surface 11B′ of the semiconductor layer 11, the intermediate structure shown in FIG. 13 is flipped over and then bonded to a carrier S1 via a bonding layer 41 (e.g., a molding material or an encapsulation material). In some embodiments, the bonding layer 41 may be disposed on the top of the structure shown in FIG. 13, covering the electrode structure 16 and the dielectric structure 14, and then bonded to the carrier S1. In some embodiments, a backside grinding process and/or a chemical mechanical polishing (CMP) process may be applied to the surface 11B′ of the substrate 10 shown in FIG. 13 until the bottom 164B of the vertical portion 164 is exposed. The bottom surface of the semiconductor layer 11 becomes 11B as shown. In some embodiments, after the bottom 164B of the vertical portion 164 is exposed, the semiconductor layer 11 is etched to further remove a portion of the semiconductor layer 11, causing the bottom 164B of the vertical portion 164 to protrude from the semiconductor layer 11. That is, a portion of the semiconductor layer 11 may be removed from the surface 11B′ of the semiconductor layer 11 such that the bottom surface 164B of the vertical portion 164 is exposed and protrude from the semiconductor layer 11 (from the bottom surface 11B of the semiconductor layer 11). Thus, a portion of the vertical portion 164 at its bottom surface 164B protrudes out of the bottom surface 11B of the semiconductor layer 11. The bottom 164B of the vertical portion 164 protruding from the semiconductor layer 11 helps reduce ohmic contact resistance and improve heat dissipation. The substrate 10 is thinned such that all the vertical portion 164 are exposed and protrude from the bottom surface 11B of the substrate 10. In some embodiments, the substrate 10 after being thinned may have a thickness ranging from 30 to 100 micrometers (μm).

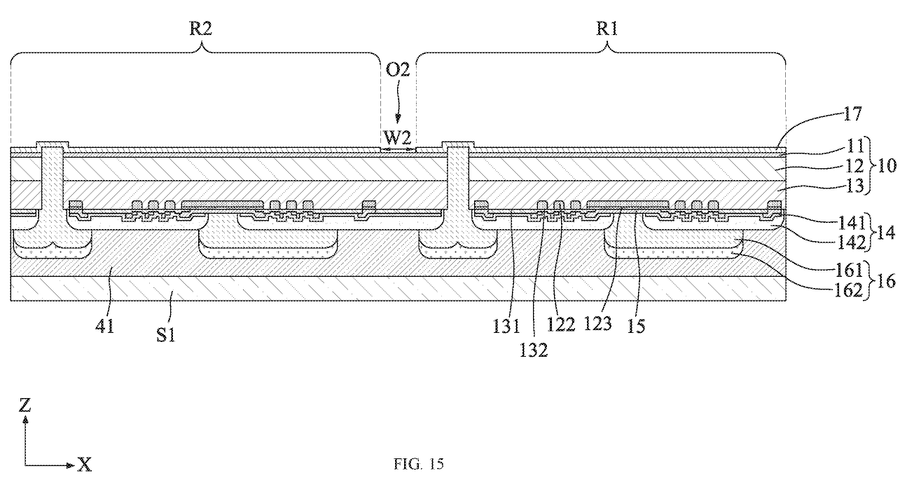

Referring to FIG. 15, the manufacturing method includes forming the electrode structure 17 on the surface 11B of the semiconductor layer 11, where the electrode structure 17 has an opening O2 defining the location of the isolation structure 18 to be formed later. The opening O2 extends from the surface 11B of the semiconductor layer 11 away from the semiconductor layer 11, and exposes a portion of the semiconductor layer 11 (consequently, a portion of the substrate). In some embodiments, forming the electrode structure 17 may include: forming a metal material layer on the surface 11B of the semiconductor layer 11 by sputtering; forming a patterned photoresist layer on the metal material layer; etching the metal material layer using the patterned photoresist layer as a mask to form the electrode structure 17 having the opening O2; and removing the patterned photoresist layer. In some embodiments, after forming the electrode structure 17, a thermal annealing process (e.g., laser annealing) may be performed on the electrode structure 17 in order to form a low-resistance ohmic contact between the electrode structure 17 and the semiconductor layer 11. Because the vertical portions 164 of the cathodes (e.g., the cathodes 16b and 16d) are exposed and protrude from the surface 11B of the semiconductor layer 11, the electrode structure 17 contacts the bottoms 164B of the vertical portions 164 and conformally covers the portions of the vertical portions 164 protruding from the semiconductor layer 11. In some embodiments, the electrode structure 17 contacts the bottom surfaces and sidewalls of the vertical portions 164 protruding from semiconductor layer 11. The molding material layer 19 is disposed onto the surface 11B of the substrate 10 and onto the portion of the vertical portion 14 protruding from the surface 11B of the substrate 10. The portion of the vertical portion 14 protruding from the surface 11B of the substrate 10 is surrounded by the molding material layer 19. The opening O2 in the electrode structure 17 defines the location of the molding material layer 19 to be formed later between the dies. Therefore, it can be understood that, from the top view, the opening O2 surrounds each region (e.g., R1 and R2 ) of the substrate 10. In some embodiments, the opening O2 has a width W2. In some embodiments, the vertical projection of the opening O2 is located in the periphery of the regions R1 and R2 and separated from the doped regions 121. The opening O2 does not overlap with the vertical portions 164 in the top view.

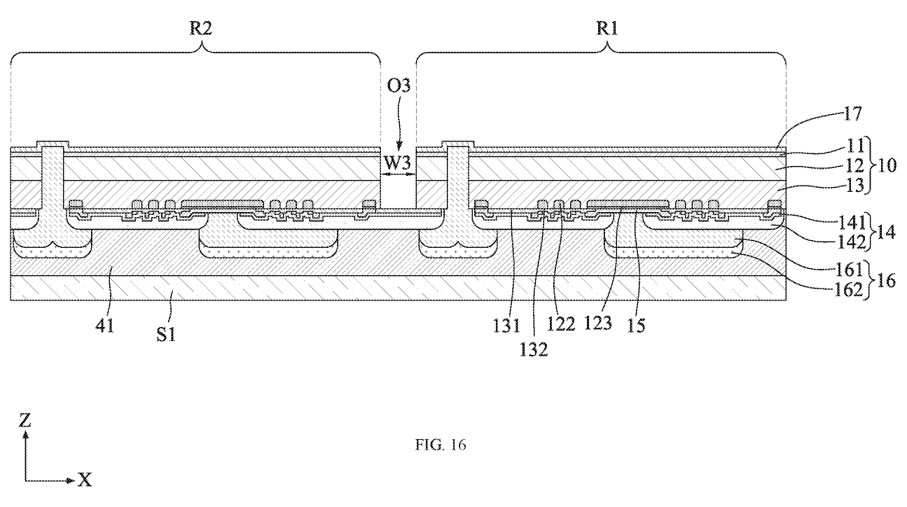

Referring to FIG. 16, the manufacturing method includes etching the substrate 10 exposed by the electrode structure 17 to form an opening O3 extending through the substrate 10. In some embodiments, forming the opening O3 may include: forming a patterned photoresist layer on the electrode structure 17, where the patterned photoresist layer has an opening corresponding to and overlapping with the opening O3; performing an etching process (e.g., wet etching or dry etching) on the substrate 10 using the patterned photoresist layer as a mask; and removing the patterned photoresist layer. In some embodiments, the patterned photoresist layer defining the electrode structure 17 in the step of FIG. 15 and the patterned photoresist layer defining the opening O3 in the substrate 10 in the step of FIG. 16 may be formed using the same photomask, and thus the patterned photoresist layers in both steps may have the same pattern. In some embodiments, a wet etching process is used to form the opening O2 of the electrode structure 17. This wet etching process causes the sidewalls of the electrode structure 17 to recede. Therefore, even using the same photomask, the width W2 of the opening O2 increases in the step of FIG. 16. The increased width W2 of the opening O2 is substantially greater than the width W3 of the opening O3. That is, W2 is greater than W3. In other embodiments, the patterned photoresist layers in the steps of FIGS. 15 and 16 are formed using different photomasks, and the patterned photoresist layer in the step of FIG. 16 has a pattern corresponding to the patterned photoresist layer in the step of FIG. 15, but with a smaller opening width. Therefore, the width W2 of the opening O2 remains the same in the steps of FIGS. 15 and 16, and the width W2 of opening O2 is greater than the width W3 of the opening O3. The opening O3 extends from the surface 11B of the semiconductor layer 11 to the top surface 13A of the second epitaxial layer 13 extending through the thickness of the substrate 10. In some embodiments, the dielectric layer 132 may serve as an etch stop layer. Therefore, the etching process that removes a portion of substrate 10 stops at the dielectric layer 132, and the opening O3 exposes a portion of dielectric layer 132.

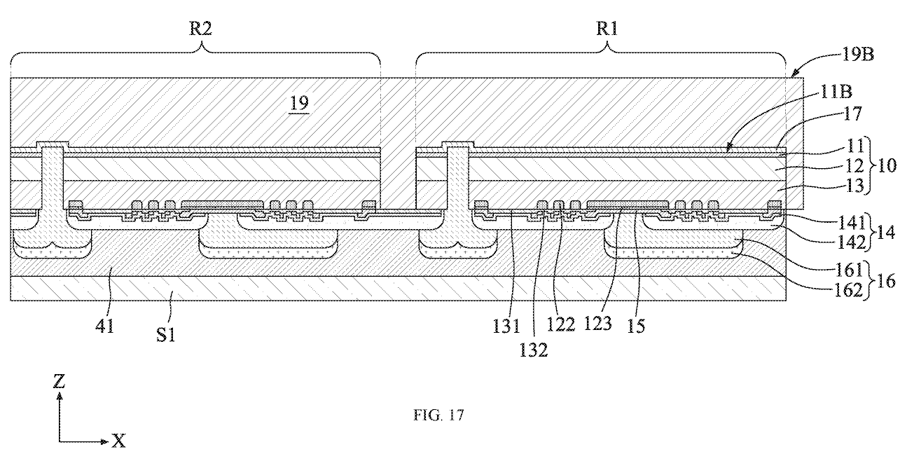

Referring to FIG. 17, the manufacturing method includes forming the molding material layer 19, where the molding material layer 19 fills the openings O2 and O3 and covers the electrode structure 17. The openings O2 and O3 may be located in the scribe line region (e.g., dicing streets) of divided regions of the substrate 10, and the molding material layer 19 fills the scribe line region to electrically isolate different regions of the substrate 10. The molding material layer 19 also protects the electrode structure 17 from moisture and oxidation. Furthermore, small thickness of the substrate 10 may result in structural instability of the semiconductor device, the molding material layer 19 provides additional support to improve the durability of the semiconductor device such that the semiconductor device has sufficient stability as needed. In some embodiments, the molding material layer 19 is formed by a coating or deposition process on the surface 11B of the semiconductor layer 11. In some embodiments, the molding material layer 19 contacts the dielectric layer 132. The molding material layer 19 may contact the portion of the dielectric layer 132 exposed by the opening O3. In some embodiments, the width of the molding material layer 19 at the opening O2 is greater than the width at the opening O3. In some embodiments, the molding material layer 19 has a flat surface 19B that is away from the dielectric layer 132 and approximately parallel to the surface 11B of the semiconductor layer 11.

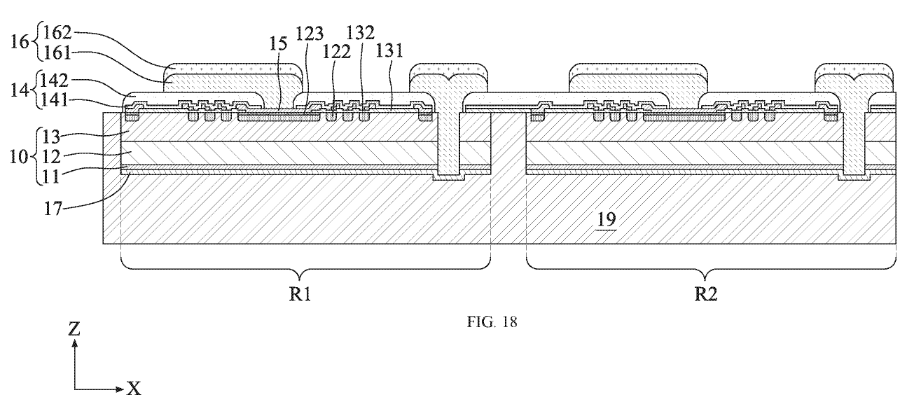

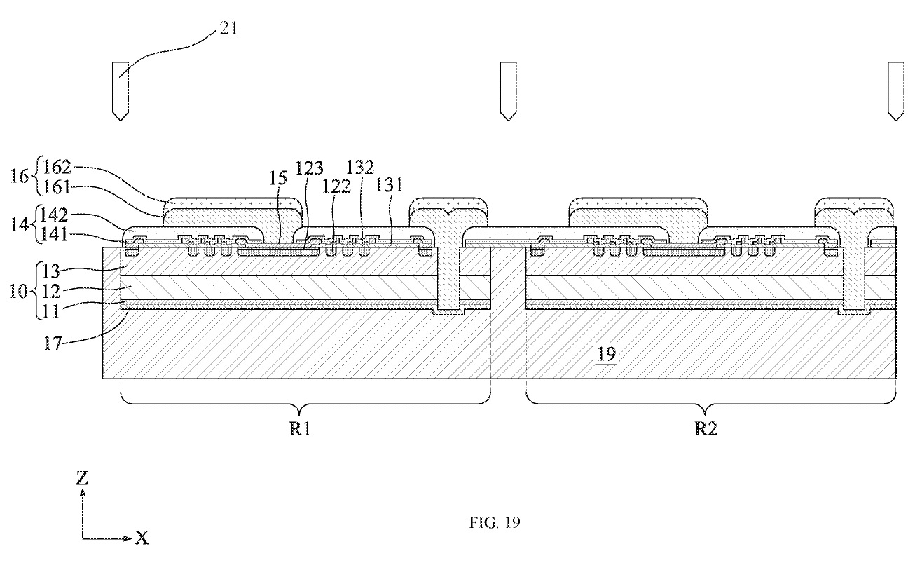

Referring to FIGS. 18-19, the manufacturing method includes peeling the intermediate structure of FIG. 17 from the carrier S1 and performing cutting from above the surface 13A of the second epitaxial layer 13 to form the semiconductor device 1 as shown in FIG. 1. Basically, the carrier S1 and the bonding layer 41 are removed, which may be implemented by various applicable methods. In some embodiments, the bonding layer 41 is a dicing tape, and may be removed by peeling off. In some embodiments, the intermediate structure of FIG. 17 is flipped over before the peeling step. Specifically, the carrier S1 and the bonding layer 41 are removed from the structure shown in FIG. 17, and the resulting structure is then flipped over so that the top surface 13A of the substrate 10 faces upward, as shown in FIG. 18. In the structure of FIG. 18, the regions R1 and R2 of the substrate 10 each include a die similar to the semiconductor device 1. Referring to FIG. 19, the structure of FIG. 18 may be diced along the direction of the cutter 21 to obtain individual dies, each of which is similar to the semiconductor device 1.

The semiconductor device 2 has a structure similar to that of the semiconductor device 1 and may be manufactured using a manufacturing method similar to that shown in FIGS. 5-19. For illustrative purposes, the following description focuses on the steps of the manufacturing method of the semiconductor device 2 that are different from those of the semiconductor device 1. For other similar steps, reference can be made to the description with respect to FIGS. 5-19 above.

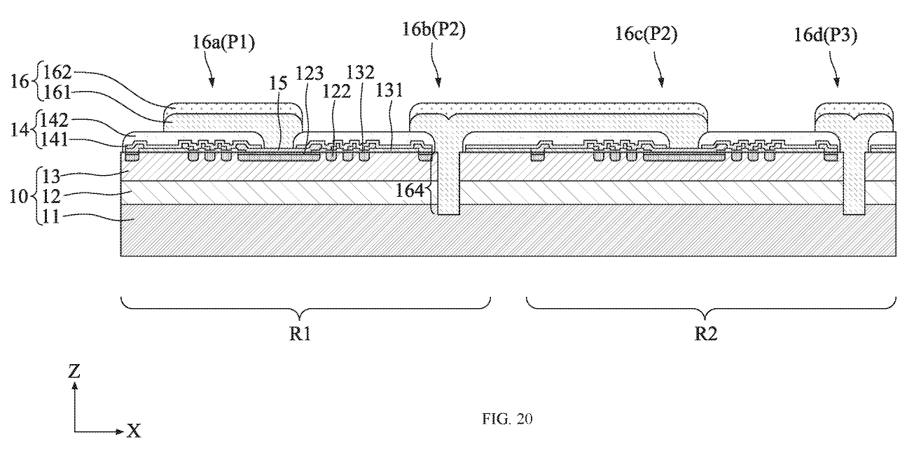

FIG. 20 is a diagram showing a stage of an embodiment manufacturing method of the semiconductor device 2, which is shown in FIG. 2. In some embodiments, the manufacturing method of the semiconductor device 2 includes performing the steps described above with respect to FIGS. 5-12. After the step of FIG. 12 is performed, the manufacturing method of the semiconductor device 2 includes forming the first conductive material layer 161 as shown in FIG. 20 to fill the multiple openings (e.g., the openings O421, O422, O423, and O424) in the second passivation layer 142 and the openings O1 in the substrate 10, and forming the second conductive material layer 162 to cover the first conductive material layer 161. The method for forming the first and second conductive material layers 161, 162 may be found in the description of FIG. 13 and will not be repeated here. The difference between FIGS. 20 and 13 regarding the first conductive material layer 161 and the second conductive material layer 162 is that the cathode 16b located in the first region R1 is connected to the anode 16c located in the second region R2.

To form the structures shown in FIGS. 2 and 3, and the circuit layout shown in FIG. 4, the first conductive material layer 161 and the second conductive material layer 162 may further cover a portion of the substrate 10 located between the first region R1 and the second region R2. Specifically, the first conductive material layer 161 of the dielectric structure not only fills in the opening O1 and the opening O422 in the first region R1, and the opening O423 in the second region R2, but also covers the dielectric structure 14 between the opening O422 and the opening O423. The second conductive material layer 162 covers the first conductive material layer 161. The first conductive material layer 161 and the second conductive material layer 162 collectively define the electrode structure 16. Based on the patterns of the first conductive material layer 161 and the second conductive material layer 162, the electrode structure 16 may be divided into multiple electrode pads P1, P2, and P3 (the electrode pad P4 is not shown and omitted). A portion of the electrode pad P1 located in first region R1 serves as the anode 16a. The electrode pad P2 covers a portion of the first region R1 and a portion of the second region R2, where a portion of the electrode pad P2 located in the first region R1 serves as the cathode 16b and a portion of electrode pad P2 located in the second region R2 serves as the anode 16c. A portion of the electrode pad P3 located in the second region R2 serves as the cathode 16d. Although the electrode pad P4 is not shown in FIG. 20, the top view of the semiconductor device 2 is already shown in FIG. 2 and will not be repeated here.

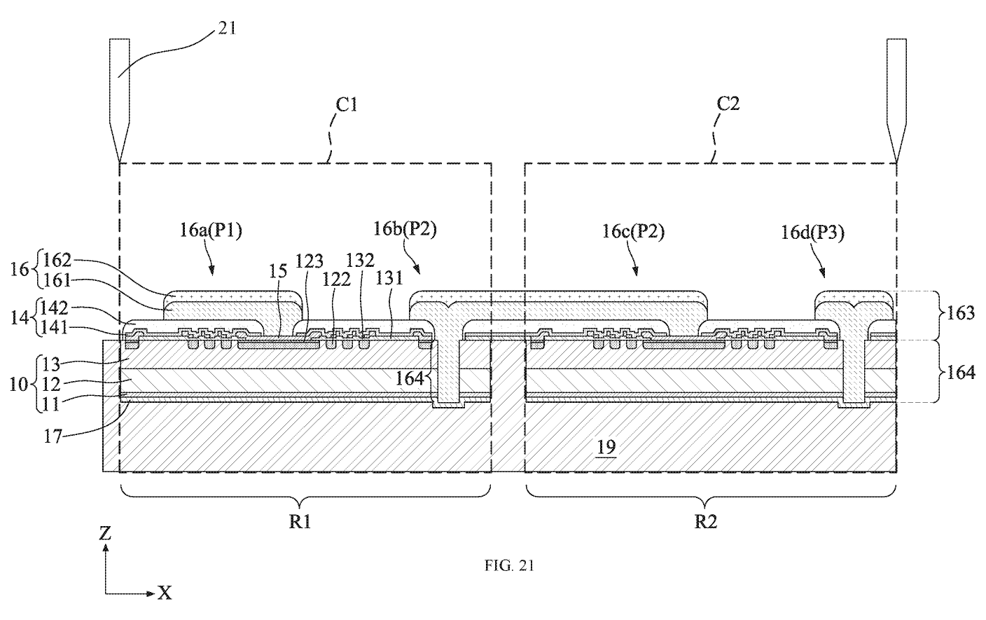

Referring to FIG. 21, the manufacturing method of the semiconductor device 2 includes: after the step of FIG. 20 is performed, performing the steps described above with respect to FIGS. 14-18, and then dicing the substrate 10 from above its top surface 12A to form the semiconductor device 2 shown in FIG. 2. The dicing may be performed along the direction of the cutter 21 as shown in FIG. 21. FIG. 21 differs from FIG. 19 in that, because the semiconductor device 2 has four connected dies C1, C2, C3, and C4, dicing may not be performed along all scribe lines, but rather in units of the four dies. Specifically, referring back to FIGS. 2, 3, and 19, the scribe line region between the first region R1 and the second region R2 may not be sawed, the scribe line region between the first region R1 and the third region R3 may not be sawed, the scribe line region between the third region R3 and the fourth region R4 may not be sawed, and the scribe line region between the second region R2 and the fourth region R4 may not be sawed. In other words, the molding material layer 19 of the semiconductor device 2 is filled in these regions, and the molding material layer 19 in these regions may contact the dielectric layer 132. In addition, compared to the semiconductor device 1, the first conductive material layer 161 and the second conductive material layer 162 of the semiconductor device 2 may further cover at least a portion of the molding material layer 19 in the scribe line regions (as shown in FIG. 2).

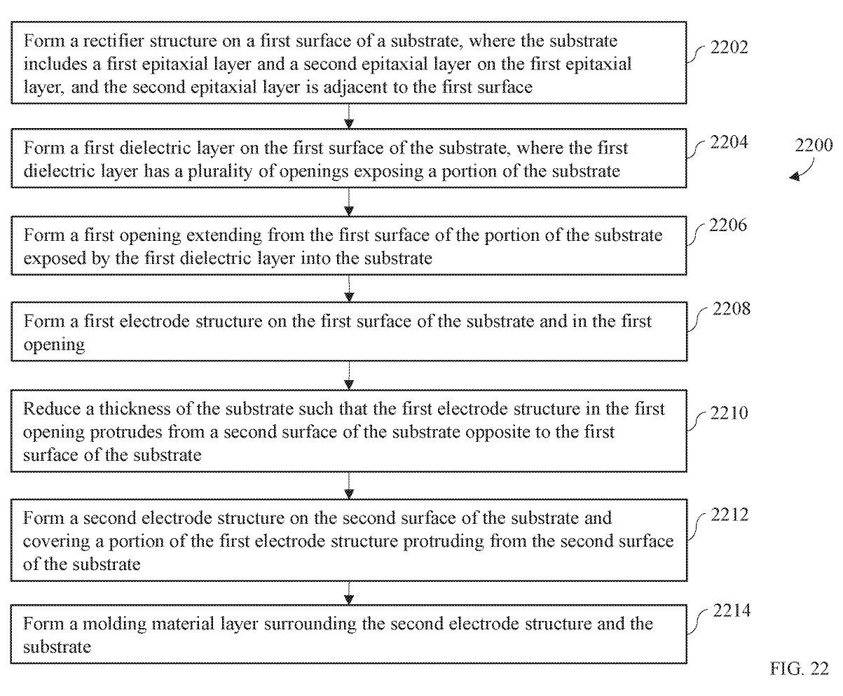

FIG. 22 is a flowchart of a method 2200 of manufacturing a semiconductor device according to embodiments of the present disclosure. The method 2200 may be representative of operations for manufacturing the semiconductor device 1 or 2 as described above. As shown, at step 2202, a rectifier structure is formed on a first surface of a substrate, where the substrate includes a first epitaxial layer and a second epitaxial layer disposed on the first epitaxial layer, and the second epitaxial layer is adjacent to the first surface. At step 2204, a first dielectric layer is formed on the first surface of the substrate, where the first dielectric layer has a plurality of openings, exposing a portion of the substrate. At step 2206, a first opening is formed extending from the first surface of the portion of the substrate exposed by the first dielectric layer into the substrate, where a depth of the first opening is greater than a thickness of the first epitaxial layer and the second epitaxial layer. At step 2208, a first electrode structure is formed on the first surface of the substrate and in the first opening. At step 2210, a thickness of the substrate is reduced such that the first electrode structure in the first opening protrudes from a second surface of the substrate opposite to the first surface of the substrate. At step 2212, a second electrode structure is formed on the second surface of the substrate and covering a portion of the first electrode structure protruding from the second surface of the substrate. At step 2214, a molding material layer is formed surrounding the second electrode structure and the substrate. The method 2200 may include other steps as described above or necessary to manufacture the embodiment semiconductor devices.

The semiconductor devices of embodiments of the present disclosure do not contain lead-containing electrical contact pads, complying with the EU environmental regulations. Compared to existing processes, the semiconductor devices of embodiments of the present disclosure have the following differences and advantages. First, the semiconductor devices disclosed herein include multiple epitaxial layers 12 and 13 with different concentrations. Unlike existing processes that achieve concentration gradients through diffusion or ion implantation within a single epitaxial layer, the use of the multiple epitaxial layers 12 and 13 allows for a greater concentration difference within a smaller thickness range. Further, the semiconductor devices disclosed herein use polyimide on the front surface (or top surface) of the semiconductor devices as a protective layer, eliminating the need of using packaging materials (or molding materials) for packaging. This not only facilitates heat dissipation but also increases forward transient current. Furthermore, the semiconductor devices disclosed herein include a cathode structure protruding from the bottom surface of the substrate 10, which not only reduces ohmic contact resistance but also further enhances the semiconductor devices' heat dissipation capabilities. In view of the above structural features, the semiconductor devices of embodiments of the present disclosure further achieve the purpose of implementing a high voltage component (e.g., voltage higher than 650 volts, or between 650 and 1500 volts) with a thinned substrate 10 (e.g., thickness less than or equal to 100 microns).

Further embodiments are provided in the following.

In an embodiment, a semiconductor device is provided that includes: a first epitaxial layer, having a first surface and a second surface opposite to each other; a second epitaxial layer, disposed on the first surface of the first epitaxial layer and having a third surface away from the first epitaxial layer; a first rectifier structure, disposed on the third surface of the second epitaxial layer; a first electrode structure, disposed on the third surface of the second epitaxial layer, the first electrode structure comprising: a first electrode pad, located on the first rectifier structure and electrically connected to the first rectifier structure; and a second electrode pad, comprising a first portion located on the third surface of the second epitaxial layer and a second portion extending from the third surface toward the second surface of the first epitaxial layer, wherein the second portion penetrates the first epitaxial layer and the second epitaxial layer, and protrudes from the second surface of the first epitaxial layer; and a second electrode structure, disposed on the second surface of the first epitaxial layer, wherein the second electrode structure contacts a bottom and a portion of sidewalls of the second portion of the second electrode pad protruding from the second surface.

Optionally, in the preceding embodiment, the first epitaxial layer and the second epitaxial layer have approximately same thickness.

Optionally, in any of the preceding applicable embodiments, a thickness of the first epitaxial layer is smaller than a thickness of the second epitaxial layer.

Optionally, in any of the preceding applicable embodiments, the first epitaxial layer and the second epitaxial layer have a same conductivity type, and a doping concentration of the second epitaxial layer is less than a doping concentration of the first epitaxial layer.

Optionally, in any of the preceding applicable embodiments, the semiconductor device further comprises: a semiconductor layer, disposed on the second surface of the first epitaxial layer, wherein the second portion of the second electrode pad passes through the semiconductor layer and protrudes from the semiconductor layer away from a fourth surface of the first epitaxial layer.

Optionally, in any of the preceding applicable embodiments, the second electrode structure extends along the fourth surface of the semiconductor layer, and covers the second portion of the second electrode pad protruding from the fourth surface of the semiconductor layer.

Optionally, in any of the preceding applicable embodiments, the semiconductor device further comprises: a first dielectric layer, disposed between the first rectifier structure and a portion of the first electrode structure, wherein a material of the first dielectric layer includes polyimide.

Optionally, in any of the preceding applicable embodiments, the first dielectric layer surrounds the second portion of the second electrode pad when viewed from a top view.

Optionally, in any of the preceding applicable embodiments, the semiconductor device further comprises: a second dielectric layer, disposed between the first rectifier structure and the first dielectric layer, wherein a material of the first dielectric layer includes silicon nitride, silicon oxide or a combination thereof.

Optionally, in any of the preceding applicable embodiments, the semiconductor device further comprises: a third dielectric layer, disposed between the second dielectric layer and the third surface of the second epitaxial layer, wherein the third dielectric layer has a dielectric material different from that of the second dielectric layer.

Optionally, in any of the preceding applicable embodiments, the semiconductor device further comprises: a molding material layer, covering the second electrode structure and surrounds sidewalls of the first epitaxial layer and the second epitaxial layer.

Optionally, in any of the preceding applicable embodiments, the semiconductor device further comprises: a substrate, comprising at least the first epitaxial layer and the second epitaxial layer stacked in a vertical direction, wherein the third surface of the second epitaxial layer is a top surface of the substrate, and the second electrode structure is disposed on a bottom surface of the substrate; a molding material layer, covering the second electrode structure, and extending from the bottom surface toward the top surface of the substrate and penetrating the substrate, wherein the molding material layer divides the substrate into at least a first region and a second region adjacent to each other in a horizontal direction; and a second rectifier structure, disposed on the top surface of the substrate, wherein the first rectifier structure is located in the first region, the second rectifier structure is located in the second region, and the first portion of the second electrode pad of the first electrode structure is electrically connected to the second rectifier structure.

Optionally, in any of the preceding applicable embodiments, the first portion of the second electrode pad is located on the third surface of the second epitaxial layer, extends in the horizontal direction and covers the molding material layer located between the first region and the second region.

Optionally, in any of the preceding applicable embodiments, the semiconductor device further comprises: a third electrode pad, having a third portion located on the top surface of the substrate, and a fourth portion extending from the third surface toward the second surface of the first epitaxial layer and passing through the substrate, wherein the fourth portion protrudes from the bottom surface of the substrate.

In another embodiment, a manufacturing method of a semiconductor power device is provided that includes: forming a rectifier structure on a first surface of a substrate, wherein the substrate comprises a first epitaxial layer and a second epitaxial layer stacked in a vertical direction, the second epitaxial layer being adjacent to the first surface and the first epitaxial layer being away from the first surface; forming a first dielectric layer covering the substrate and the rectifier structure, wherein the first dielectric layer has a plurality of openings, respectively exposing a portion of the rectifier structure and a portion of the substrate; removing the portion of the substrate exposed by the first dielectric layer to form a first opening, wherein a depth of the first opening is greater than a thickness of the first epitaxial layer and the second epitaxial layer; forming a first electrode structure on the first surface of the substrate and in the first opening; reducing a thickness of the substrate such that a bottom of the first electrode structure protrudes from the substrate; forming a second electrode structure on a second surface of the substrate opposite to the first surface, wherein the second electrode structure covers the bottom of the first electrode structure; and forming a molding material layer surrounding the second electrode structure and the substrate.

Optionally, in the preceding embodiment, the second electrode structure exposes a portion of the second surface of the substrate, and the manufacturing method further comprises: removing, from the second surface of the substrate, a portion of the substrate exposed by the second electrode structure to form a second opening, wherein the second opening passes through the substrate.

Optionally, in any of the preceding applicable embodiments, the second opening is located at a dicing street, and the molding material layer is formed in the second opening.

Optionally, in any of the preceding applicable embodiments, the manufacturing method further includes: before forming the rectifier structure, forming an etch stop layer on the first surface of the substrate.

Optionally, in any of the preceding applicable embodiments, the second opening overlaps with the etching stop layer in a vertical direction, and the second opening stops at the etching stop layer.

Optionally, in any of the preceding applicable embodiments, the substrate further includes a semiconductor layer located on the first epitaxial layer opposite to the second epitaxial layer, and after reducing the thickness of the substrate, the bottom of the first electrode structure protrudes from the semiconductor layer.

Optionally, in any of the preceding applicable embodiments, a material of the first dielectric layer comprises polyimide, and the manufacturing method further comprises: before forming the first dielectric layer, forming a second dielectric layer covering the substrate and the rectifier structure, wherein the second dielectric layer has a plurality of openings overlapping with the plurality of openings of the first dielectric layer.

Optionally, in any of the preceding applicable embodiments, a material of the second dielectric layer comprises nitride, oxide or a combination thereof.

Optionally, in any of the preceding applicable embodiments, the first epitaxial layer and the second epitaxial layer include polycrystalline silicon or single crystal silicon, the first epitaxial layer and the second epitaxial layer have a same conductivity type, and a doping concentration of the first epitaxial layer is greater than a doping concentration of the second epitaxial layer.

Optionally, in any of the preceding applicable embodiments, forming the first electrode structure comprises: forming a copper-containing metal layer on the first surface of the substrate and in the first opening by electroplating; and forming a tin-containing metal layer on the copper-containing metal layer by electroplating.

In this disclosure, for description convenience, spatially relative terms such as "below", "under", "lower", "above", "upper", "left side", "right side", and so on, may be used to describe the relationship of one component or feature with another one or more components or features, as shown in the accompanying drawings. The spatially relative terms are not only used to depict the orientations in the accompanying drawings, but also intended to encompass different orientations of a device in use or operation. A device may be oriented in other ways (rotated 90 degrees or in other orientations), and the spatially relative terms used herein may be interpreted in a corresponding way similarly. It should be understood that when a component is referred to as being "connected to" or "coupled to" another component, it can be directly connected or coupled to another component or an intervening component may be present.

As used herein, the terms "approximately", "basically", "substantially" and "about" are used to describe and account for small variations. When used in conjunction with an event or instance, the terms may refer to an embodiment of exact occurrence of an event or instance as well as an embodiment where the event or instance is close to occurrence. As used herein with respect to a given value or range, the term "about" generally means being within ±10%, ±5%, ±1%, or ±0.5% of the given value or range. A range herein may be referred to as being from one endpoint to the other or as being between two endpoints. All ranges disclosed herein are inclusive of the endpoints unless otherwise indicated. The term "substantially coplanar" may mean that the difference of positions of two surfaces with reference to the same plane is within a few micrometers (μm), e.g., within 10 μm, within 5 μm, within 1 μm, or within 0.5 μm. When values or characteristics are referred to as being "substantially" the same, the term may refer to a value that is within ±10%, ±5%, ±1%, or ±0.5% of the mean of the values.

The foregoing has outlined features of some embodiments and detailed aspects of present disclosure. The embodiments described in the present disclosure may be readily used as a basis for designing or modifying other processes and structures in order to carry out the same or similar purposes and/or to achieve the same or similar advantages of the embodiments presented herein. Such equivalent constructions do not depart from the spirit and scope of the present disclosure, and various changes, substitutions, and alterations can be made without departing from the spirit and scope of the present disclosure.

Although the description has been described in detail, it should be understood that various changes, substitutions and alterations can be made without departing from the spirit and scope of this disclosure as defined by the appended claims. Moreover, the scope of the disclosure is not intended to be limited to the particular embodiments described herein, as one of ordinary skill in the art will readily appreciate from this disclosure that processes, machines, manufacture, compositions of matter, means, methods, or steps, presently existing or later to be developed, which may perform substantially the same function or achieve substantially the same result as the corresponding embodiments described herein, may be utilized according to the present disclosure. Accordingly, the appended claims are intended to include within their scope such processes, machines, manufacture, compositions of matter, means, methods, or steps.

What is claimed:

1. A semiconductor device, comprising:
a first epitaxial layer, having a first surface and a second surface opposite to each other;
a second epitaxial layer, disposed on the first surface of the first epitaxial layer and having a third surface away from the first epitaxial layer;
a first rectifier structure, disposed on the third surface of the second epitaxial layer;
a first electrode structure comprising:
a first electrode pad, disposed on the first rectifier structure and electrically connected to the first rectifier structure; and
a second electrode pad, comprising: a first portion disposed on the third surface of the second epitaxial layer, and a second portion extending from the third surface of the second epitaxial layer toward the first epitaxial layer, extending through the second epitaxial layer and the first epitaxial layer, and protruding from the second surface of the first epitaxial layer; and
a second electrode structure, disposed on the second surface of the first epitaxial layer, and contacting and surrounding a portion of the second portion of the second electrode pad that protrudes from the second surface of the first epitaxial layer.

2. The semiconductor device of claim 1, wherein the first epitaxial layer and the second epitaxial layer have approximately a same thickness.

3. The semiconductor device of claim 1, wherein a thickness of the first epitaxial layer is smaller than a thickness of the second epitaxial layer.

4. The semiconductor device of claim 1, wherein the first epitaxial layer and the second epitaxial layer have a same conductivity type, and a doping concentration of the second epitaxial layer is less than a doping concentration of the first epitaxial layer.

5. The semiconductor device of claim 1, further comprising:
a semiconductor layer, disposed between the second surface of the first epitaxial layer and the second electrode structure, wherein the second portion of the second electrode pad passes through the semiconductor layer.

6. The semiconductor device of claim 1, further comprising:
a first dielectric layer, disposed between the first rectifier structure and a portion of the first electrode structure, wherein a material of the first dielectric layer includes polyimide.

7. The semiconductor device of claim 6, wherein the first dielectric layer surrounds the second portion of the second electrode pad in a top view of the semiconductor device.

8. The semiconductor device of claim 6, further comprising:
a second dielectric layer, disposed between the first rectifier structure and the first dielectric layer, wherein a material of the second dielectric layer includes silicon nitride, silicon oxide or a combination thereof.

9. The semiconductor device of claim 8, further comprising:
a third dielectric layer, disposed between the second dielectric layer and the third surface of the second epitaxial layer, wherein the third dielectric layer has a dielectric material different from that of the second dielectric layer.

10. The semiconductor device of claim 1, further comprising:
a molding material layer, disposed on and covering the second electrode structure, and surrounding sidewalls of the first epitaxial layer and the second epitaxial layer.

11. The semiconductor device of claim 1, further comprising:
a molding material layer that comprises:
a first portion covering the second electrode structure, and
a second portion extending from a bottom surface of a substrate of the semiconductor device toward the third surface of the second epitaxial layer and penetrating the substrate, the substrate comprising at least the first epitaxial layer and the second epitaxial layer disposed on the first epitaxial layer, wherein the substrate comprises at least a first region and a second region separated by the second portion of the molding material layer, and the first rectifier structure is located in the first region; and
a second rectifier structure, disposed on the third surface of the second epitaxial layer and in the second region, the first portion of the second electrode pad being electrically connected to the second rectifier structure.

12. The semiconductor device of claim 11, wherein the first portion of the second electrode pad on the third surface of the second epitaxial layer covers the molding material layer between the first region and the second region.

13. The semiconductor device of claim 11, further comprising:
a third electrode pad in the second region, having a third portion located on the third surface of the second epitaxial layer, and a fourth portion extending from the third surface of the second epitaxial layer toward the first epitaxial layer, passing through the substrate, and protruding from the bottom surface of the substrate.

14. A method comprising:
forming a rectifier structure on a first surface of a substrate, the substrate comprising a first epitaxial layer and a second epitaxial layer disposed on the first epitaxial layer, the second epitaxial layer being adjacent to the first surface of the substrate;
forming a first dielectric layer on the first surface of the substrate, the first dielectric layer having a plurality of openings exposing a portion of the substrate;
forming a first opening extending into the substrate from the first surface of the portion of the substrate exposed by the first dielectric layer, wherein a depth of the first opening is greater than a thickness of the first epitaxial layer and the second epitaxial layer;
forming a first electrode structure on the first surface of the substrate and in the first opening;
reducing a thickness of the substrate such that the first electrode structure in the first opening protrudes from a second surface of the substrate opposite to the first surface of the substrate;
forming a second electrode structure on the second surface of the substrate and covering a portion of the first electrode structure protruding from the second surface of the substrate; and
forming a molding material layer surrounding the second electrode structure and the substrate.

15. The method of claim 14, further comprising:
forming a second opening extending, toward the first surface of the substrate, from the second surface of a portion of the substrate exposed by an opening of the second electrode structure, the second opening passing through the substrate.

16. The method of claim 15, wherein the second opening is located at a dicing street, and the molding material layer is formed in the second opening.

17. The method of claim 14, wherein the substrate further includes a semiconductor layer located on the first epitaxial layer opposite to the second epitaxial layer, and after reducing the thickness of the substrate, the first electrode structure protrudes from the semiconductor layer.

18. The method of claim 14, wherein the plurality of openings of the first dielectric layer further expose a portion of the rectifier structure; and
forming the first electrode structure comprises forming a portion of the first electrode structure on the exposed portion of the rectifier structure.

19. The method of claim 14, wherein the first epitaxial layer and the second epitaxial layer include polycrystalline silicon or single crystal silicon, the first epitaxial layer and the second epitaxial layer have a same conductivity type, a doping concentration of the first epitaxial layer is greater than a doping concentration of the second epitaxial layer, and a material of the first dielectric layer comprises polyimide.

20. A semiconductor device, comprising:
a substrate comprising a semiconductor layer, a first epitaxial layer disposed on the semiconductor layer, and a second epitaxial layer disposed on the first epitaxial layer;
a first rectifier structure disposed on a top surface of the substrate in a first region of the substrate, and a second rectifier structure disposed on the top surface of the substrate in a second region of the substrate adjacent to the first region;
a first electrode disposed in the first region, on the first rectifier structure and electrically connected to the first rectifier structure;
a second electrode in the first region, comprising:
a first portion disposed on the top surface of the substrate;
a second portion extending from the top surface of the substrate, through the substrate, and protruding from the substrate;
a third electrode disposed in the second region, on the second rectifier structure and electrically connected to the second rectifier structure, the third electrode electrically connected to the first portion of the second electrode;
an electrode structure on a bottom surface of the substrate and covering a portion of the second portion that protrudes from the substrate; and
a molding material layer extending from the top surface of the substrate through the substrate, and separating the first region and the second region.
